(19) United States
(12) Patent Application Publication
(10) Pub. No.: US 2026/0150327 A1
(43) Pub. Date: May 28, 2026

(54) SEMICONDUCTOR NANOSTRUCTURES AND METHODS OF FORMING THE SAME

(71) Applicant: Taiwan Semiconductor Manufacturing Co., Ltd., Hsinchu (TW)

(72) Inventors: Yi-Cheng Li, Yunlin (TW); Ta-Chun Ma, New Taipei City (TW); Ming-Hua Yu, Hsinchu (TW)

(21) Appl. No.: 18/962,248

(22) Filed: Nov. 27, 2024

(51) Int. Cl. H10D 30/00; H10D 30/01; H10D 30/67

(52) U.S. Cl. CPC H10D 30/506; H10D 30/0193; H10D 30/6735

(57) ABSTRACT

A method includes forming a stack of n-type nanostructures over a substrate; forming a stack of p-type nanostructures over the substrate; performing a trim process on the stack of n-type nanostructures and the stack of p-type nanostructures, wherein the trim process etches surfaces of the n-type nanostructures at a first rate and etches surfaces of the p-type nanostructures at a second rate that is different from the first rate; forming a first gate structure on the stack of n-type nanostructures; and forming a second gate structure on the stack of p-type nanostructures.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6, 7, 8A, 8B, 8C, 9A, 9B, 9C, 10, 11A, 11B, 11C, 12A, 12B, 12C, 13A, 13B, 13C, 14A, 14B, 14C, 15A, 15B, 15C, 16A, 16B, and 16C are views of intermediate stages in the manufacturing of nanostructure-FETs, in accordance with some embodiments.

FIG. 17 illustrates magnified cross-sectional views of nanostructure-FETs, in accordance with some embodiments.

FIGS. 18A, 18B, 18C, 19A, 19B, 19C, 20A, 20B, and 20C are views of intermediate stages in the manufacturing of nanostructure-FETs, in accordance with some embodiments.

FIGS. 21A and 21B illustrate cross-sectional views and magnified cross-sectional views of nanostructure-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a trim process is performed on the nanostructures of both n-type nanostructure-FETs and p-type nanostructure-FETs. The trim process may etch the n-type nanostructures differently than the p-type nanostructures. For example, the n-type nanostructures and the p-type nanostructures may have different thicknesses after performing the trim process. This allows for improved process flexibility and improved device performance. The trim process described herein can also form different nanostructure profiles, such as nanostructures having flat or concave surfaces.

Embodiments are described below in a particular context, a die comprising nanostructure field-effect transistors (e.g., “nanostructure-FETs”). Various embodiments may be applied, however, to dies comprising other types of transistors (e.g., fin field-effect transistors (FinFETs), planar transistors, or the like) in lieu of or in combination with the nanostructure-FETs.

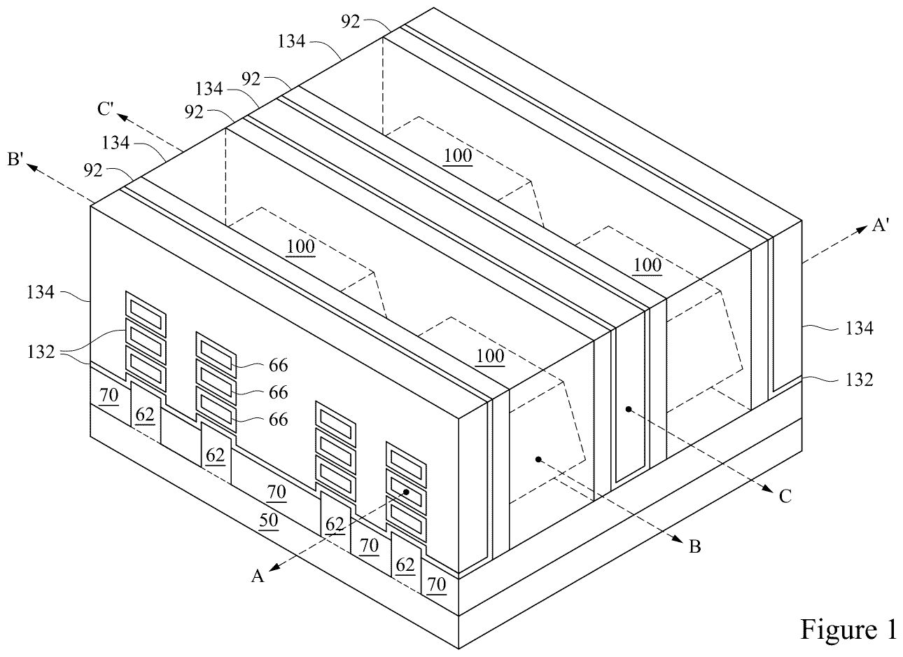

FIG. 1 illustrates an example of nanostructure-FETs (e.g., nanowire FETs, nanosheet FETs), gate-all-around (GAA) FETs, nano-FETs, or the like) in a three-dimensional view, in accordance with some embodiments. Some features of the nanostructure-FETs may be omitted from FIG. 1 for clarity. The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 132 are over top surfaces of the fins 62 and along top surfaces, sidewalls, and bottom surfaces of the nanostructures 66. Gate electrodes 134 are over the gate dielectrics 132. Source/drain regions 100 are disposed on the fins 62 at opposing sides of the gate dielectrics 132 and the gate electrodes 134. Source/drain region(s) 100 may refer to a source or a drain, individually or collectively dependent upon the context. An inter-layer dielectric (ILD) 124 is formed over the source/drain regions 100. Contacts (subsequently described) to the source/drain regions 100 will be formed through the ILD 124. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 100 of the nanostructure-FET. Cross-section B-B′ is perpendicular to cross-section A-A′ and extends through source/drain regions 100 of the nanostructure-FETs. Cross-section C-C′ is parallel to cross-section B-B′ and along a longitudinal axis of a gate electrode 134. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

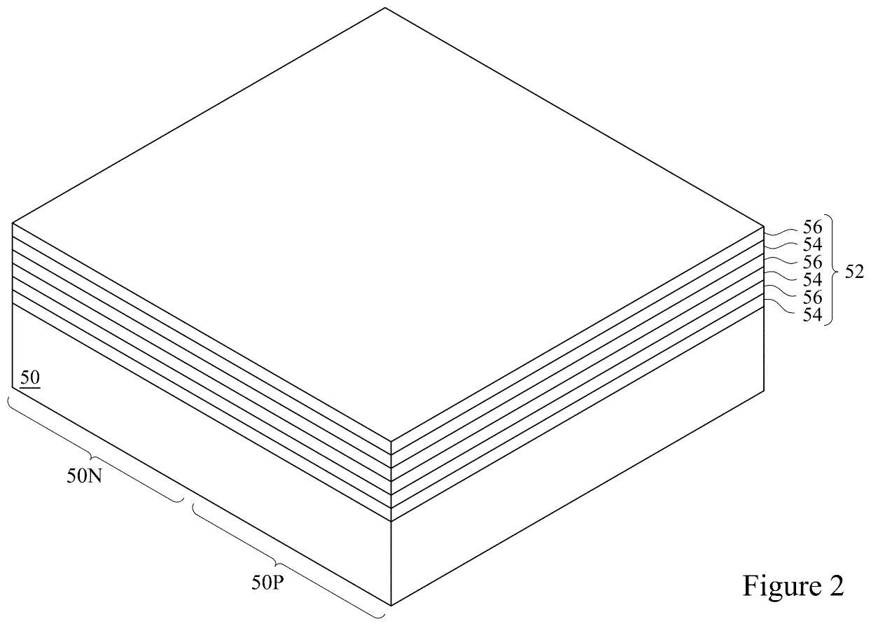

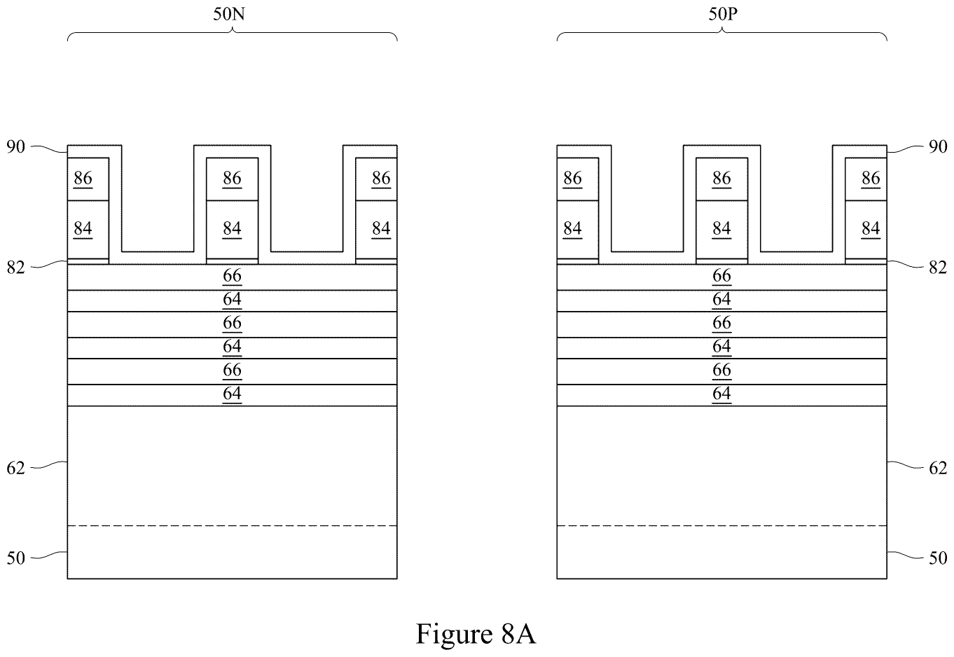

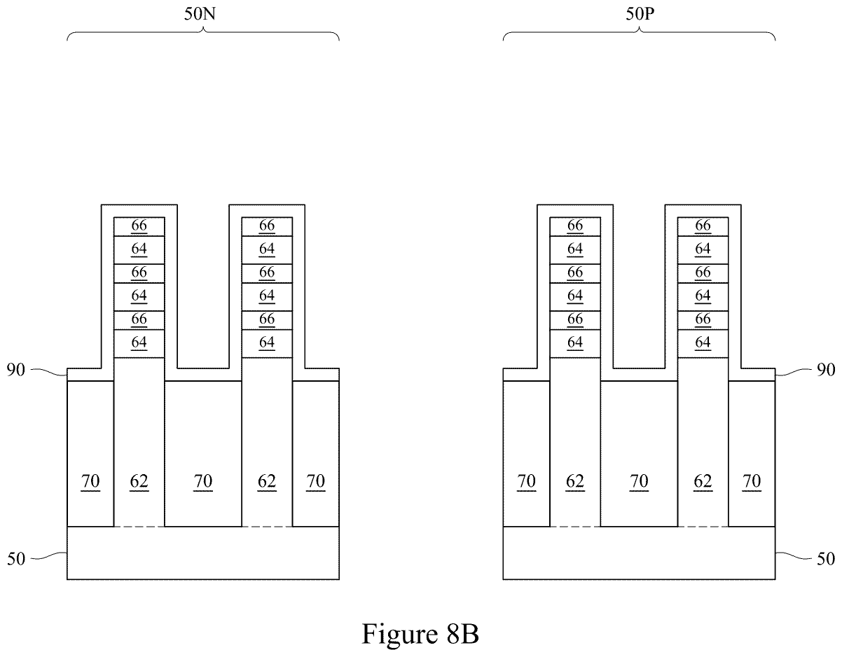

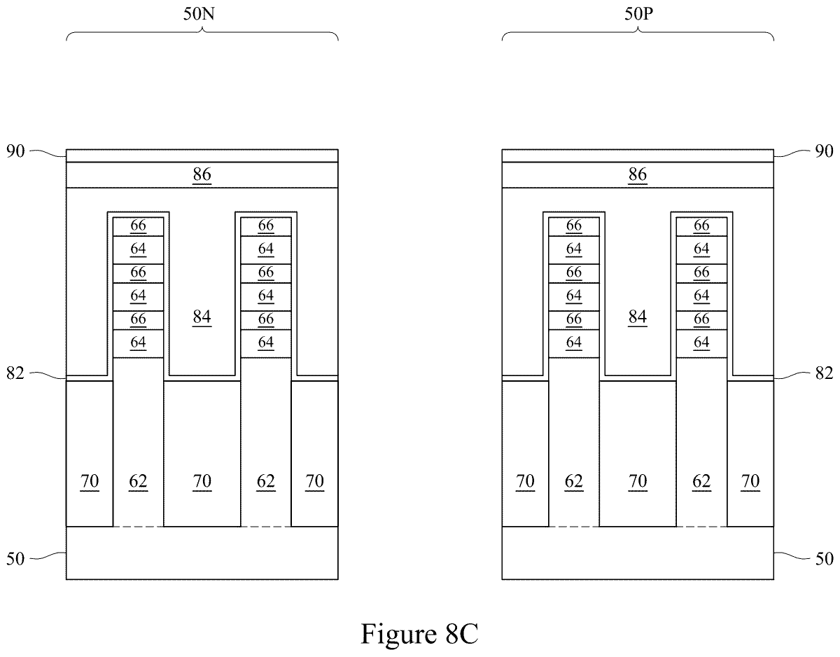

FIGS. 2-20C are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10, 11A, 12A, 13A, 14A, 15A, 16A, 17, 18A, 19A, and 20A illustrate cross-sectional views along a similar cross-section as reference cross-section A-A′ in FIG. 1. FIGS. 8B, 9B, 11B, 12B, 13B, 14B, 15B, 16B, 18B, 19B, and 20B illustrate cross-sectional views along a similar cross-section as reference cross-section B-B′ in FIG. 1. FIGS. 8C, 9C, 11C, 12C, 13C, 14C, 15C, 16C, 18C, 19C, and 20C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or a n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has a n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. As described below, the shape, thickness, profile, dimensions, or other characteristics of the channel regions in the n-type region 50N may be different from those of the channel regions in the p-type region 50P. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

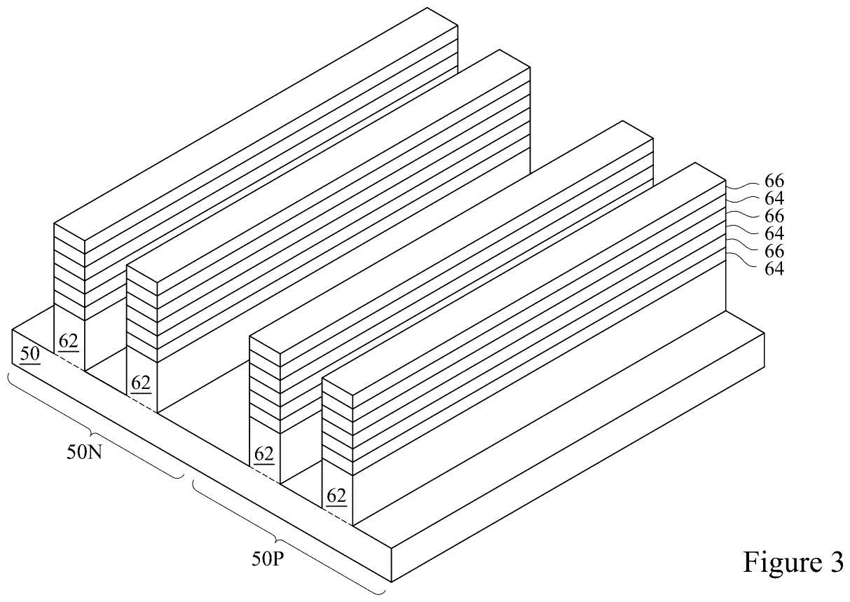

In FIG. 3, fins 62 are formed in the substrate 50, and nanostructures 64 and nanostructures 66 (collectively referred to as “nanostructures 64/66”) are formed in the multi-layer stack 52. In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56.

The fins 62 and the nanostructures 64/66 may be patterned by any suitable method. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66.

The fins 62 are illustrated as having substantially equal widths in both the n-type region 50N and the p-type region 50P. In some embodiments, the widths of the fins 62 in the n-type region 50N may be greater or less than the width of the fins 62 in the p-type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

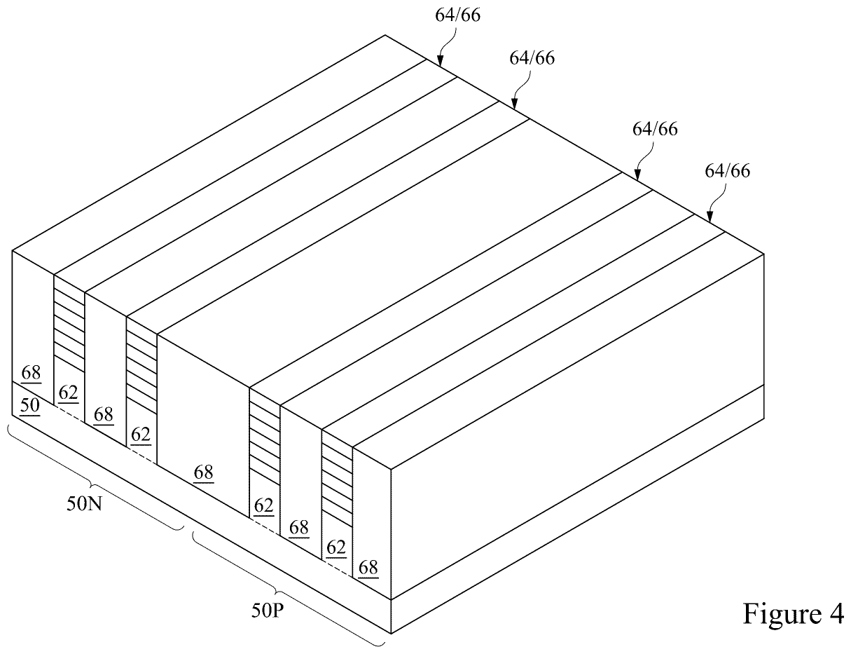

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process exposes the nanostructures 64/66 such that top surfaces of the nanostructures 64/66 and the insulation material 68 are level after the planarization process is complete.

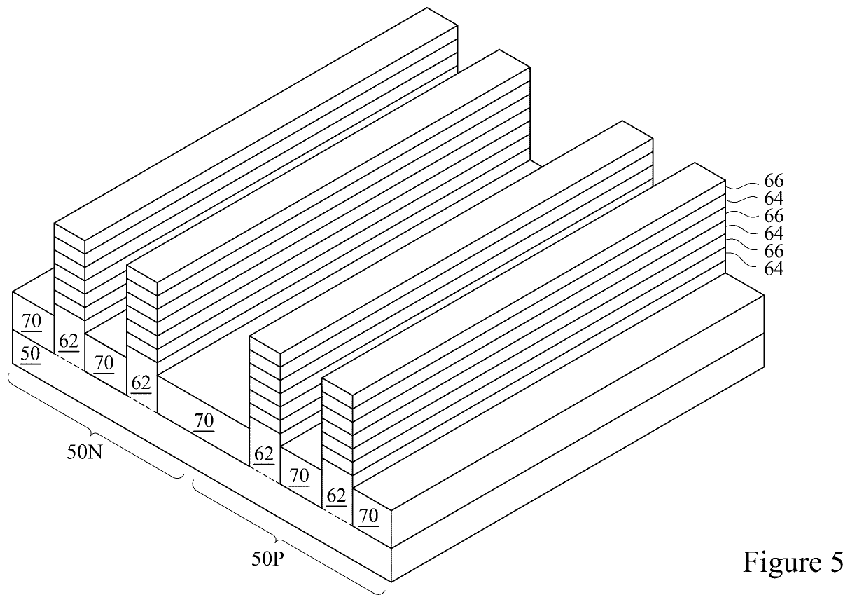

In FIG. 5, the insulation material 68 is recessed to form STI regions 70. The STI regions 70 are adjacent the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64/66, and/or the STI regions 70. In some embodiments, the wells may be formed prior to formation of the multi-layer stack 52. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, a n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

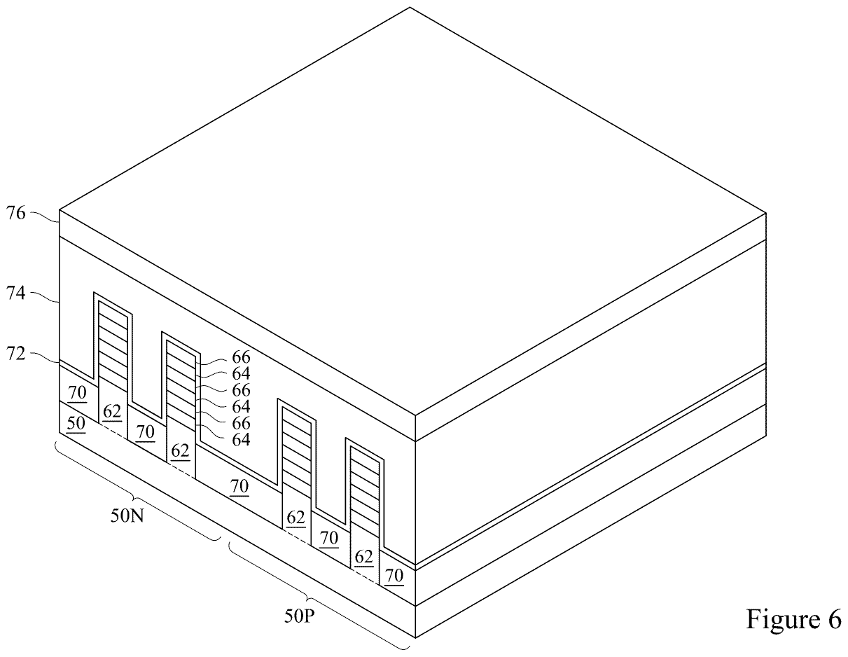

In FIG. 6, a dummy dielectric layer 72 is formed on the fins 62 and/or the nanostructures 64/66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The dummy gate layer 74 may be formed of a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62 and/or the nanostructures 64/66.

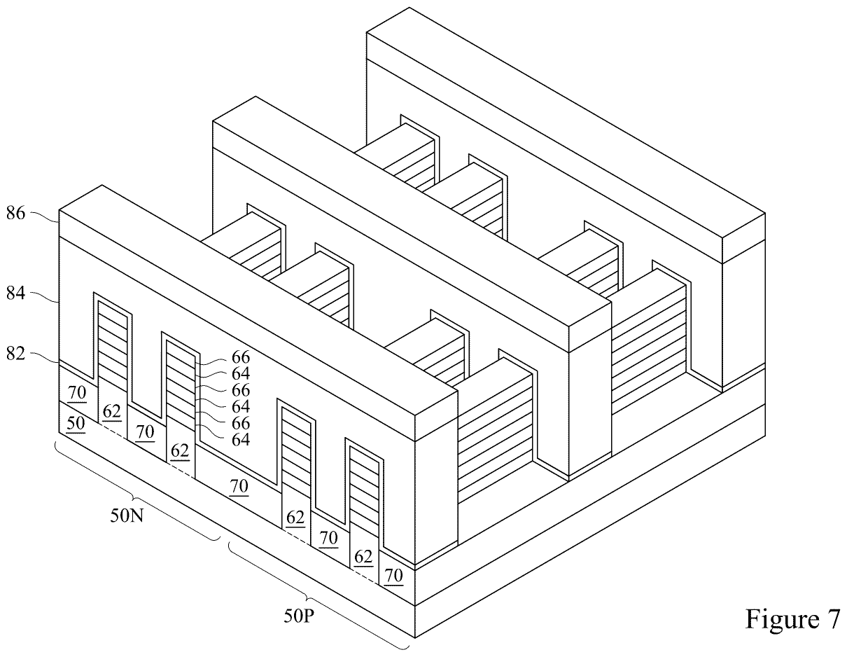

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIGS. 8A-8C, a spacer layer 90 is conformally formed over the nanostructures 64/66 and the STI regions 70, on exposed sidewalls of the masks 86 (if present), the dummy gates 84, the dummy dielectrics 82, the nanostructures 64/66, and the fins 62. The spacer layer 90 may be formed of one or more dielectric material(s). FIGS. 8A-8C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 will be subsequently etched to form spacers.

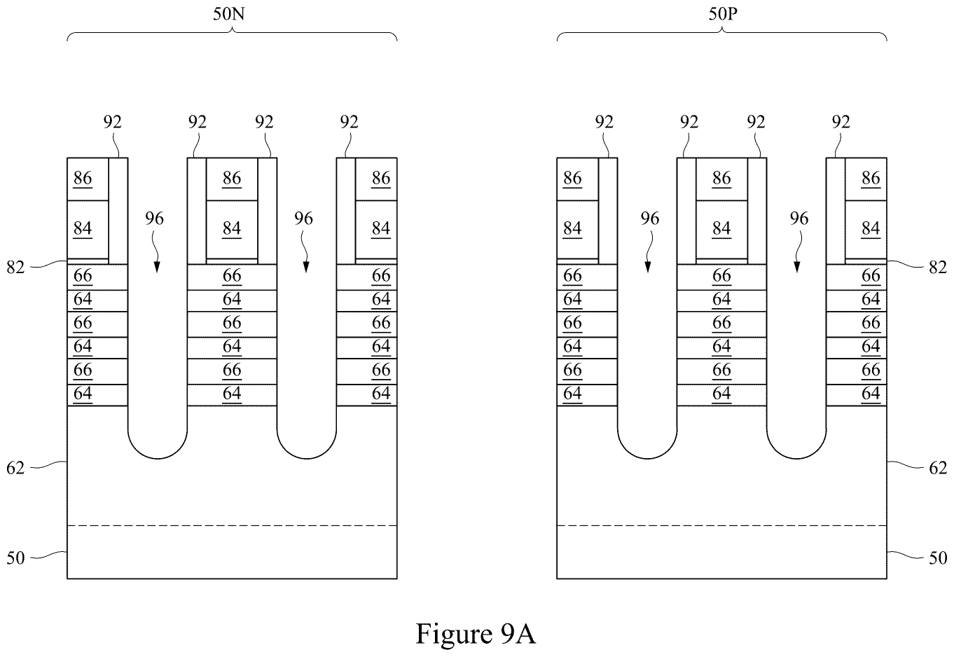

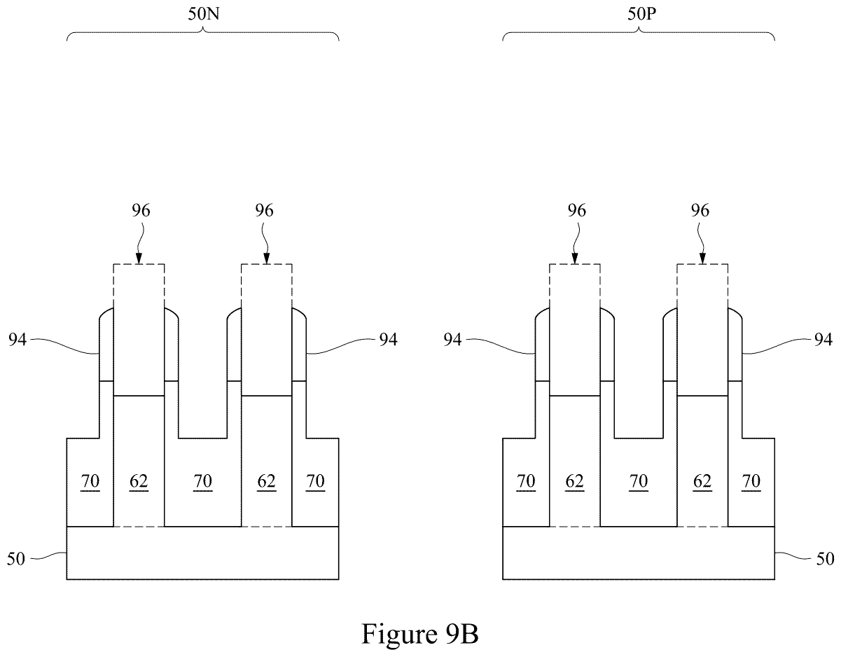

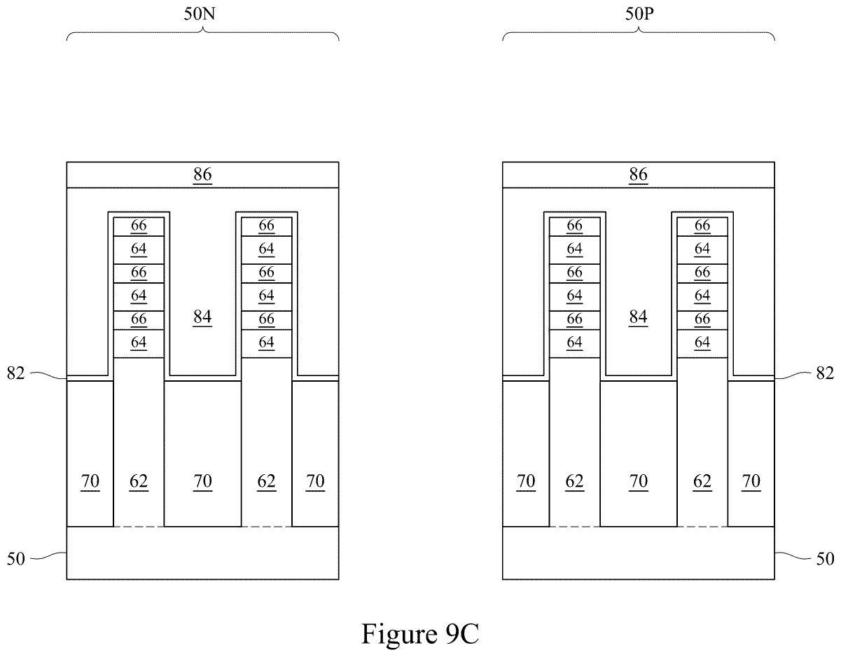

In FIGS. 9A-9C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. Additionally, the STI regions 70 may also be etched when patterning the spacer layer 90. The etching may recess portions of the STI regions 70 between the fins 62.

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 9A-9C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are disposed below the top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, and the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth.

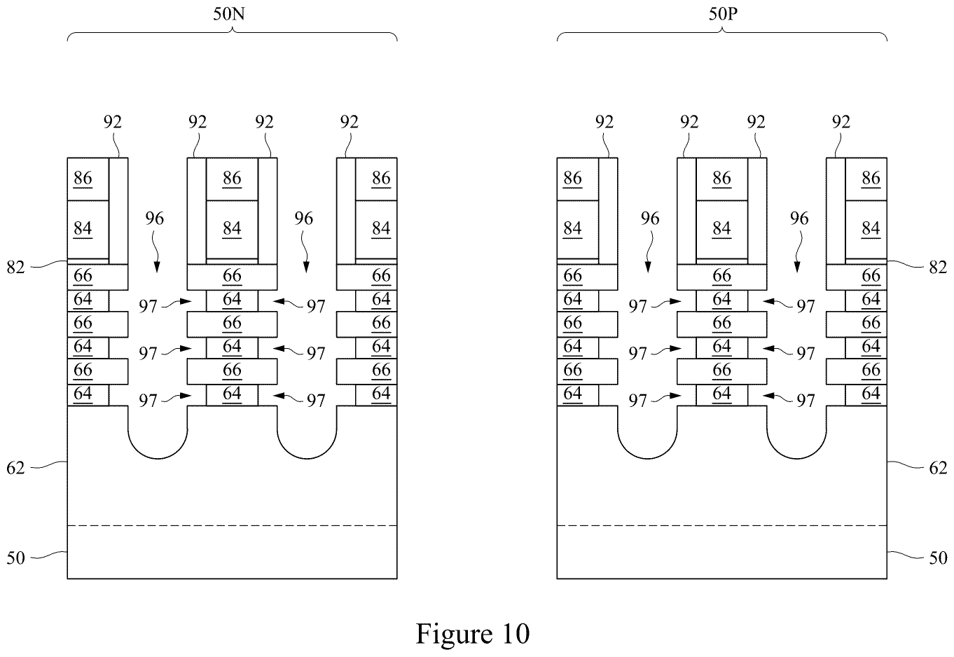

In FIG. 10, the source/drain recesses 96 are laterally expanded to form sidewall recesses 97 in the first nanostructures 64, in accordance with some embodiments. Specifically, portions of the sidewalls of the first nanostructures 64 exposed by the source/drain recesses 96 may be recessed to form sidewall recesses 97. Accordingly, a sidewall recess 97 may have a height that is about the same as a height (e.g., a thickness) of its corresponding first nanostructure 64. Although sidewalls of the first nanostructures 64 within the sidewall recesses 97 are illustrated as being flat, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some cases, the etch process may slightly recess (e.g., remove portions of) the second nanostructures 66 exposed by the sidewall recesses 97 as the sidewall recesses 97 are formed (not illustrated). In such cases, a sidewall recess 97 may have a height that is larger than the height (e.g., the thickness) of its corresponding first nanostructure 64. In some embodiments, the same etch process may be continually performed to both form the source/drain recesses 96 and recess the sidewalls of the first nanostructures 64 to form the sidewall recesses 97. In some cases, the sidewall recesses 97 may be considered part of the source/drain recesses 96.

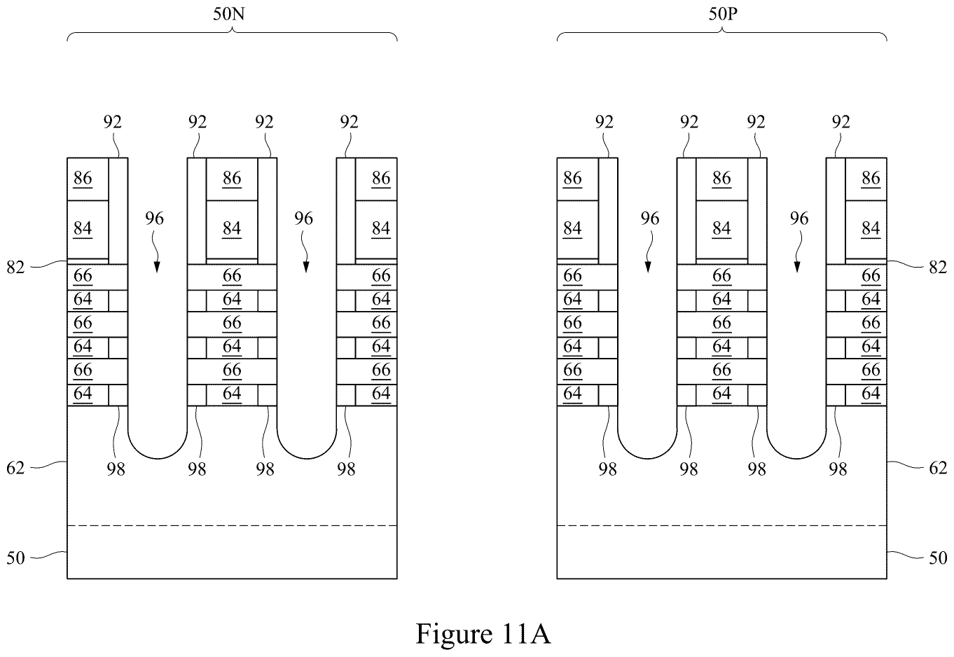

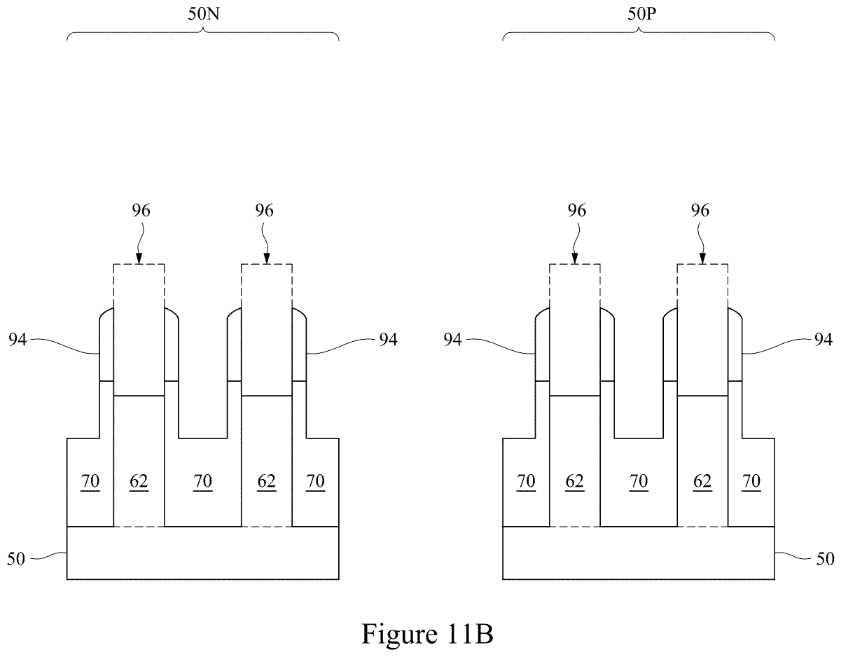

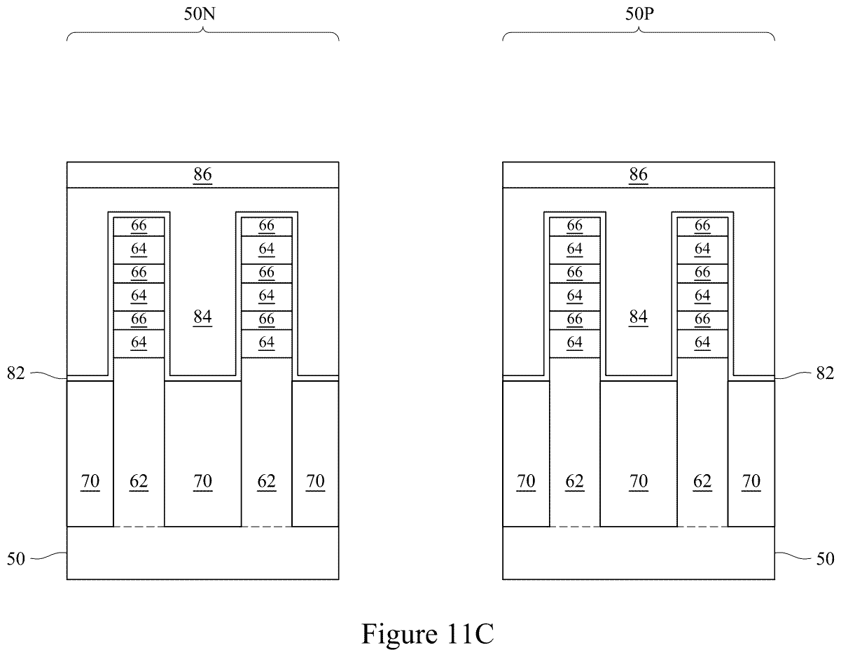

In FIGS. 11A-11C, inner spacers 98 are in the sidewall recesses 97, in accordance with some embodiments. In other words, the inner spacers 98 are formed on the sidewalls of the remaining portions of the first nanostructures 64. As will be subsequently described in greater detail, source/drain regions will be subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to subsequently remove the first nanostructures 64.

In some embodiments, the inner spacers 98 are formed by conformally forming an insulating material in the source/drain recesses 96 and in the sidewall recesses 97, and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98.

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat, the sidewalls of the inner spacers 98 may be concave or convex. In some embodiments, an inner spacer 98 may have a thickness that is about the same as or greater than a thickness of an adjacent first nanostructure 64.

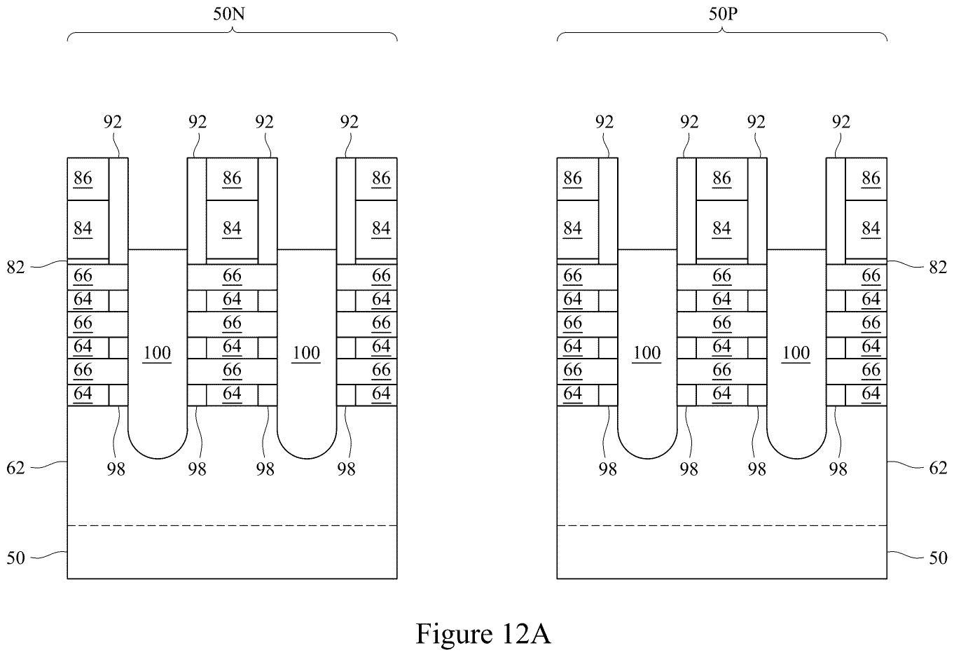

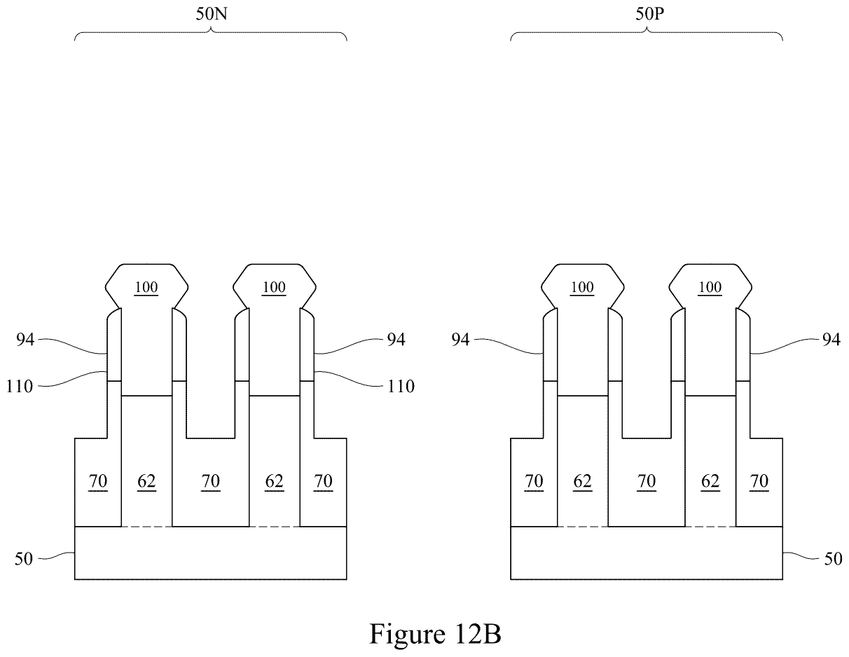

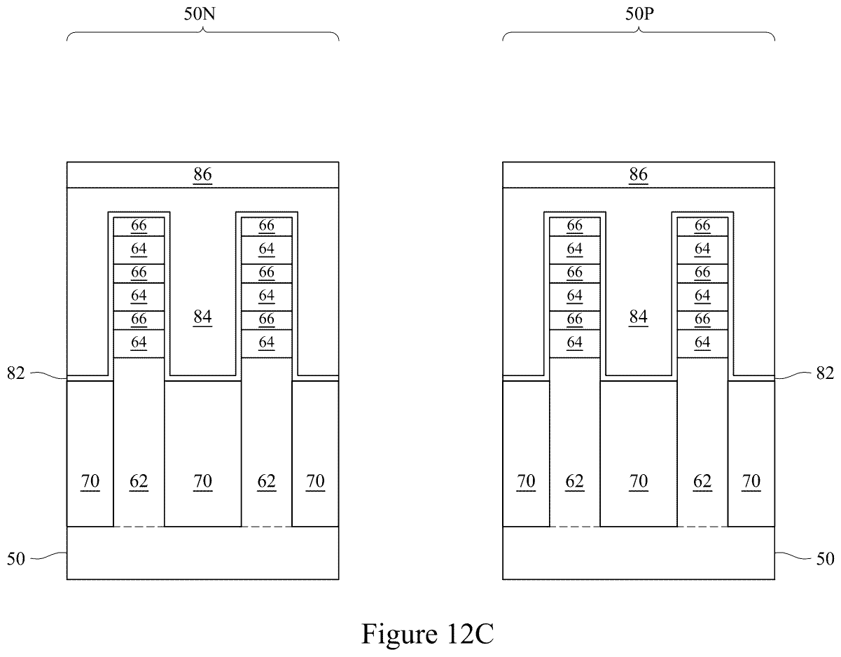

In FIGS. 12A-12C, epitaxial source/drain regions 100 are formed in the source/drain recesses 96 of the n-type region 50N and in the source/drain recesses 96 of the p-type region 50P, in accordance with some embodiments. The epitaxial source/drain regions 100 in the n-type region 50N may be referred to as “n-type source/drain regions,” and the epitaxial source/drain regions 100 in the p-type region 50P may be referred to as “p-type source/drain regions.” The n-type source/drain regions 100 may be formed before, after, or simultaneously with the formation of the p-type source/drain regions 100. In some embodiments, a semiconductor layer (not illustrated) may be formed in the source/drain recesses 96 before forming the epitaxial source/drain regions 100 in the source/drain recesses 96. The semiconductor layer may comprise, for example, undoped silicon or the like. In other embodiments, an insulating layer (not illustrated) may be deposited in the source/drain recesses before forming the epitaxial source/drain regions 100 in the source/drain recesses 96.

In some embodiments, the epitaxial source/drain regions 100 exert stress in the respective channel regions of the second nanostructures 66 within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 64 by an appropriate lateral distance such that the epitaxial source/drain regions 100 do not short out with subsequently formed gates of the resulting p-type nanostructure-FETs.

The epitaxial source/drain regions 100 may also have surfaces raised from respective surfaces of the nanostructures 64/66 and may have facets. For example, as a result of the epitaxy processes used to form the epitaxial source/drain regions 100, upper surfaces of the epitaxial source/drain regions 100 can have facets which expand laterally outward beyond sidewalls of the nanostructures 64/66. In some embodiments, these facets cause adjacent epitaxial source/drain regions 100 of a same nanostructure-FET to merge. In other embodiments, adjacent epitaxial source/drain regions 100 remain separated after the epitaxy process is completed, as illustrated by FIG. 12B. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is controlled to not form the fin spacers 94, so as to allow the epitaxial source/drain regions 100 to extend to the surface of the STI region 70. In some embodiments, the epitaxial source/drain regions 100 extend above the top surface of the nanostructures 66. As a result, the top surface of an epitaxial source/drain region 100 may be disposed further from the substrate 50 than the top surface of the adjacent nanostructures 66.

The p-type source/drain regions 100 may be formed by an epitaxy process, such as such as vapor phase epitaxy (VPE), molecular beam epitaxy (MBE), or the like. The p-type source/drain regions 100 may include any acceptable material appropriate for p-type nanostructure-FETs. For example, if the second nanostructures 66 are formed of silicon, the p-type source/drain regions 100 may comprise materials exerting a compressive strain on the second nanostructures 66, such as silicon germanium, boron doped silicon germanium, germanium, germanium tin, or the like. The p-type source/drain regions 100 may be formed of a single layer of semiconductor material or may be formed of two or more sublayers of semiconductor materials. The epitaxial source/drain regions 100, the nanostructures 64/66, and/or the fins 62 within the p-type region 50P may be implanted with dopants, similar to the process previously discussed for forming lightly-doped source/drain regions, followed by an anneal. The p-type source/drain regions 100 may have an impurity concentration of between about 10¹⁹ atoms/cm³ to about 10²¹ atoms/cm³. Other concentrations are possible. In some embodiments, the p-type source/drain regions 100 may be in situ doped during growth.

The n-type source/drain regions 100 may be formed by an epitaxy process, such as such as VPE, MBE, or the like. The n-type source/drain regions 100 may include any acceptable material appropriate for n-type nanostructure-FETs. For example, if the second nanostructures 66 are formed of silicon, the n-type source/drain regions 100 may comprise materials exerting a tensile strain on the second nanostructures 66, such as silicon, silicon carbide, phosphorous doped silicon carbide, silicon phosphide (SiP), or the like. The n-type source/drain regions 100 may be formed of a single layer of semiconductor material or may be formed of two or more sublayers of semiconductor materials. The epitaxial source/drain regions 100, the nanostructures 64/66, and/or the fins 62 within the n-type region 50N may be implanted with dopants, similar to the process previously discussed for forming lightly-doped source/drain regions, followed by an anneal. The n-type source/drain regions 100 may have an impurity concentration of between about 10¹⁹ atoms/cm³ to about 10²¹ atoms/cm³. Other concentrations are possible. In some embodiments, the n-type source/drain regions 100 may be in situ doped during growth.

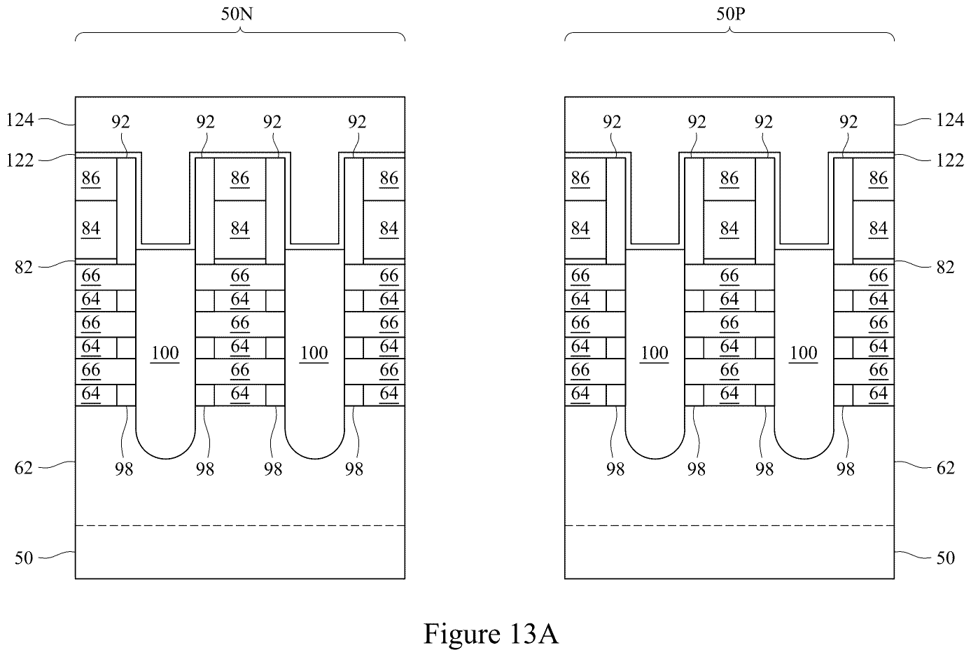

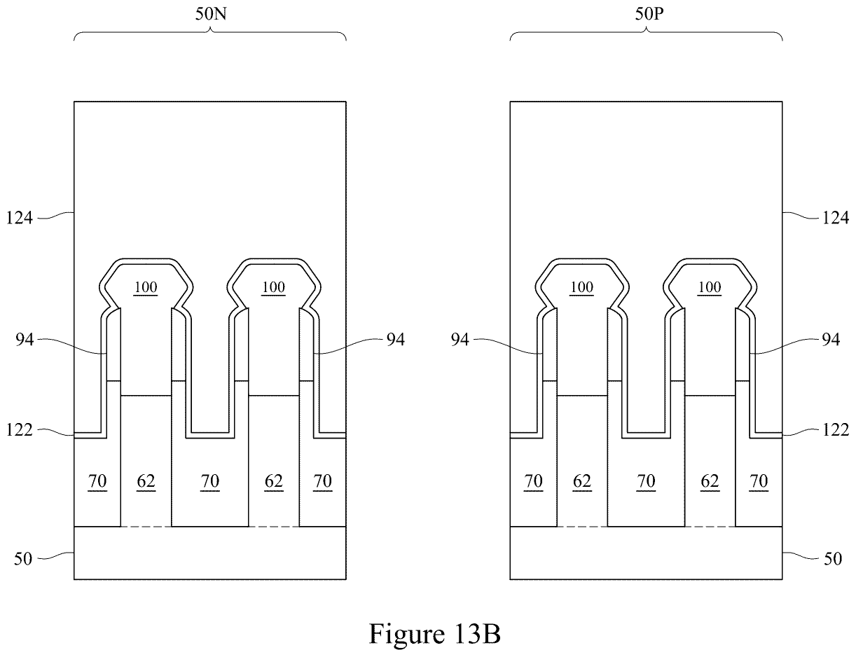

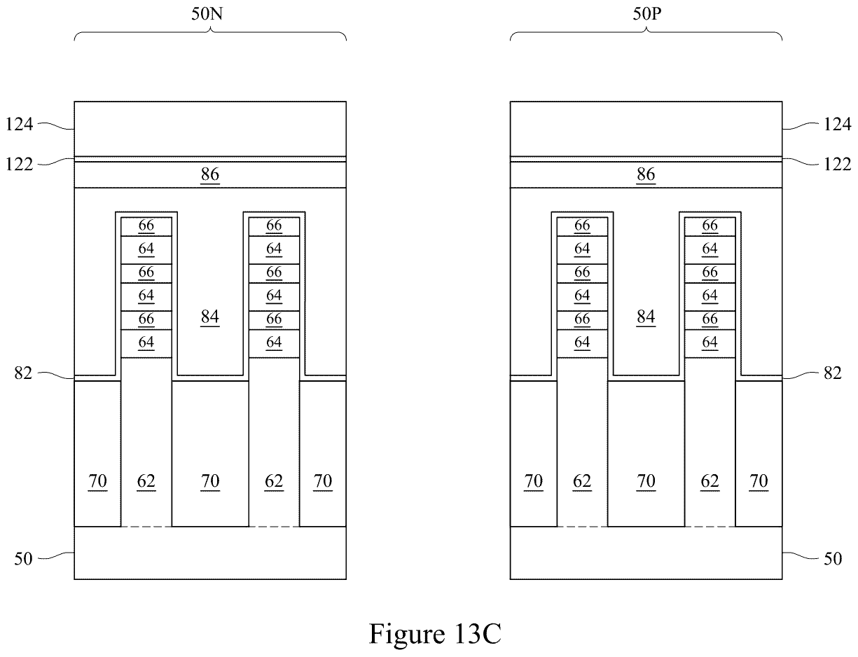

In FIGS. 13A-13C, a first ILD 124 is deposited over the epitaxial source/drain regions 100, the fin spacers 94, the gate spacers 92, the masks 86 (if present), and/or the dummy gates 84. The first ILD 124 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 122 is formed between the first ILD 124 and the epitaxial source/drain regions 100, the fin spacers 94, the gate spacers 92, the masks 86 (if present), and/or the dummy gates 84. The CESL 122 may be formed of a dielectric material having a high etching selectivity from the etching of the first ILD 124, such as silicon nitride, silicon oxide, silicon oxynitride, a combination thereof, or the like, which may be formed using any suitable deposition process, such as CVD, ALD, or the like. In one embodiment, CESL 122 is thinner than the first ILD 124. In another embodiment, the dielectric constant of CESL 122 is larger than the dielectric constant of the ILD 124.

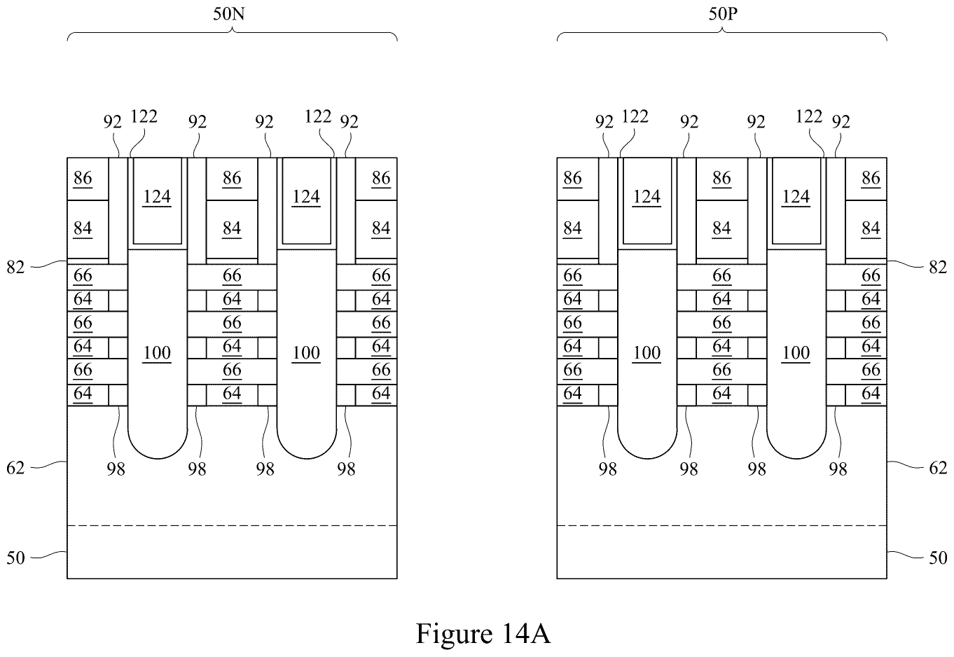

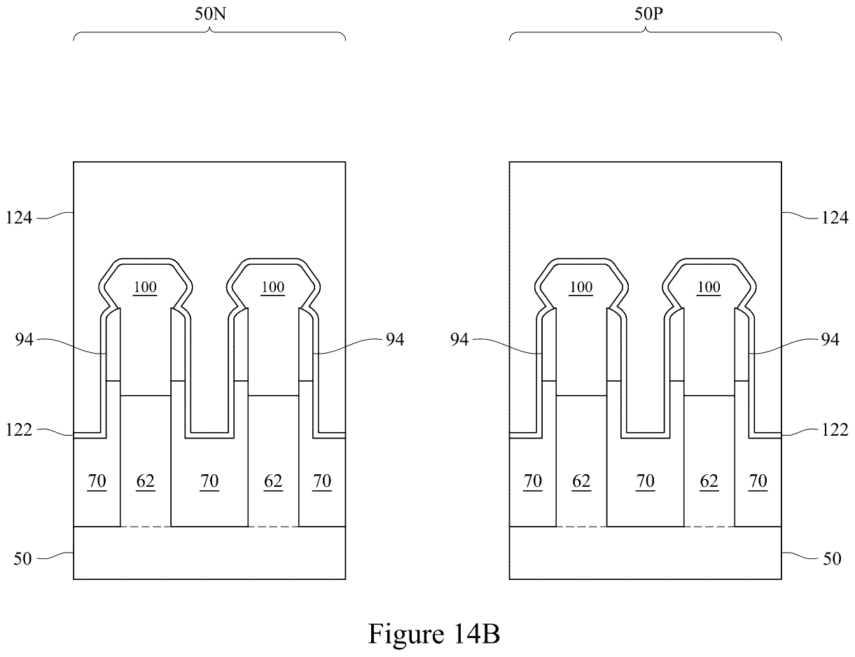

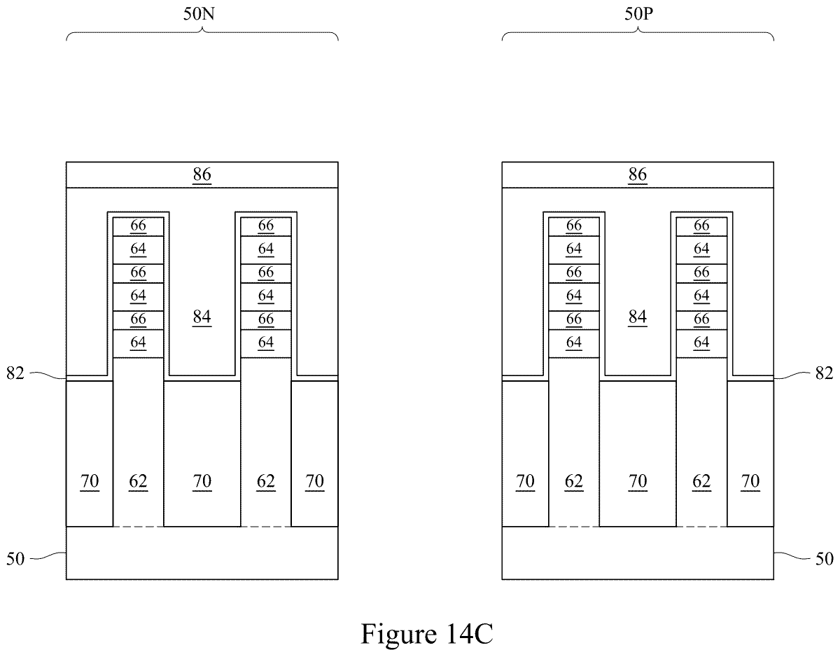

In FIGS. 14A-14C, a removal process is performed to level the top surfaces of the first ILD 124 with the top surfaces of the gate spacers 92 and the masks 86 (if present) or the dummy gates 84. In some embodiments, the removal process comprises a planarization process such as a chemical mechanical polish (CMP), a grinding process, an etch-back process, a combination thereof, or the like. The planarization process may also remove the masks 86 on the dummy gates 84, and portions of the gate spacers 92 along sidewalls of the masks 86. After the planarization process, top surfaces of the first ILD 124, the gate spacers 92, and the masks 86 (if present), and/or the dummy gates 84 are substantially level or coplanar (within process variations). Accordingly, the top surfaces of the masks 86 (if present) and/or the dummy gates 84 may be exposed through the first ILD 124.

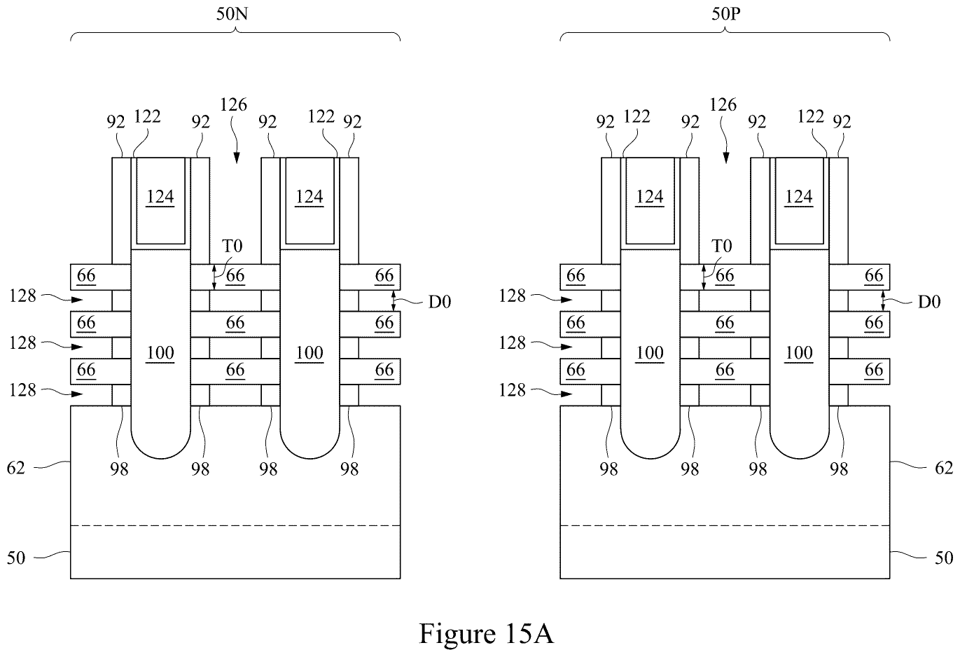

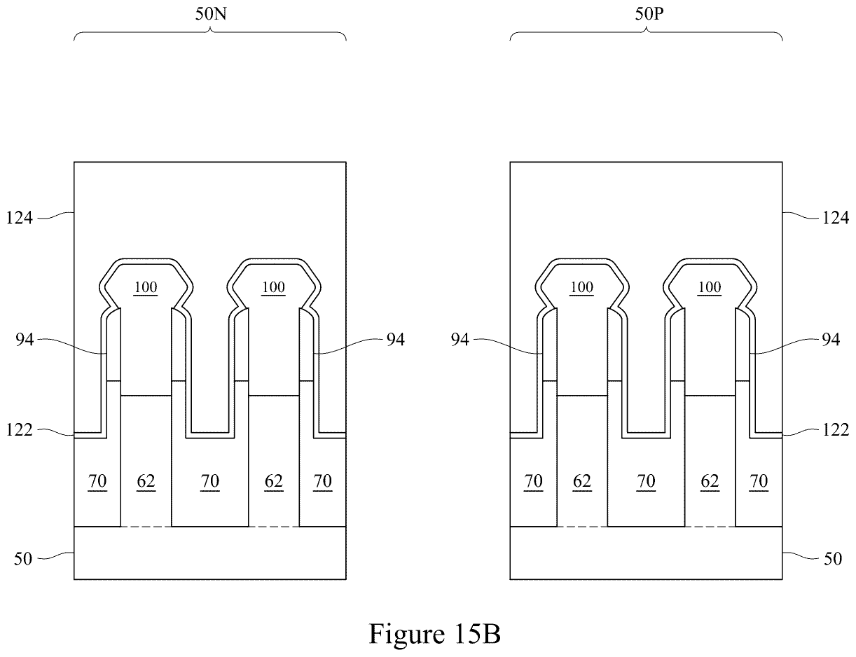

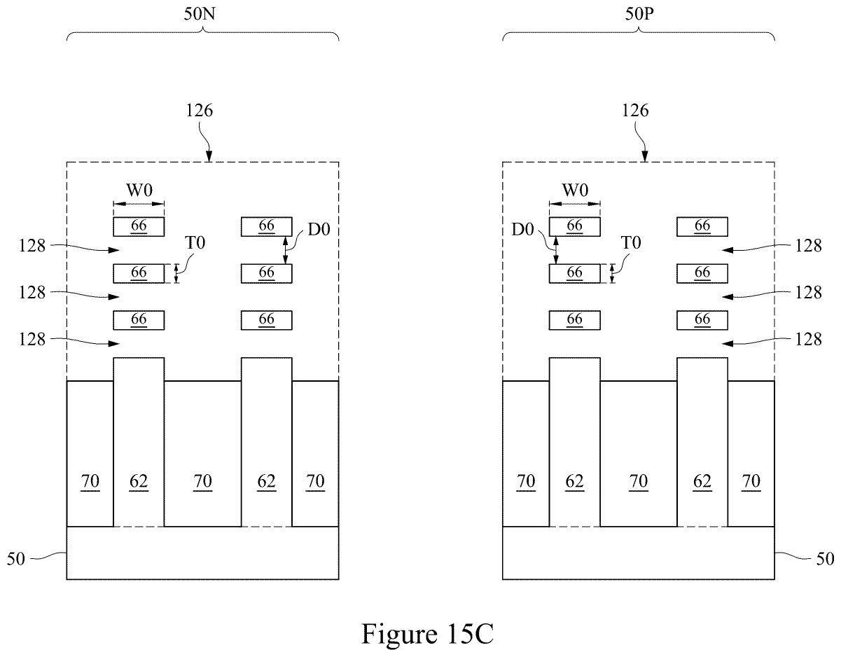

In FIGS. 15A-15C, the masks 86 (if present) and the dummy gates 84 are removed in one or more etching steps, such that recesses 126 are formed between the gate spacers 92. Portions of the dummy dielectrics 82 in the recesses 126 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 124 and the gate spacers 92. Each recess 126 exposes and/or overlies portions of nanostructures 64/66, which act as the channel regions in subsequently completed nanostructure-FETs. Portions of the nanostructures 64/66 which act as the channel regions are disposed between neighboring pairs of the epitaxial source/drain regions 113 in the n-type region 50N or between neighboring pairs of the epitaxial source/drain regions 103 in the p-type region 50P. During the removal, the dummy dielectrics 82 may be used as etch stop layers when the dummy gates 84 are etched. The dummy dielectrics 82 may then be removed after the removal of the dummy gates 84.

The remaining portions of the first nanostructures 64 are then removed to form openings 128 in regions between the second nanostructures 66. The remaining portions of the first nanostructures 64 can be removed by any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch process comprising tetramethylammonium hydroxide (TMAH), ammonium hydroxide (NH₄OH), or the like. In other embodiments, the etch process may comprise a dry etch process comprising fluorine (F₂), ammonia (NH₃), hydrofluoric acid (HF), chlorine trifluoride (ClF₃), XeF₃, or the like. The etch process that removes the remaining portions of the first nanostructures 64 may be considered a “first etch process” in some cases. Hereinafter, the second nanostructures 66 may be referred to as nanostructures 66, and the nanostructures 66 over each fin 62 may be referred to as “stacks” of nanostructures 66.

In some embodiments, after removing the first nanostructures 64, the second nanostructures 66 may have a thickness T0 that is in the range of about 3 nm to about 10 nm, though other thicknesses are possible. In some embodiments, the vertical distance D0 between neighboring second nanostructures 66 (e.g., a height of an opening 128) may be in the range of about 2 nm to about 13 nm, though other distances are possible. In some embodiments, the second nanostructures 66 have a width W0 that is in the range of about 6 nm to about 85 nm, though other widths are possible. In some embodiments, the second nanostructures 66 in both the n-type region 50N and the p-type region 50P have about the same thickness T0, about the same distance D0, and/or about the same width W0. In other words, prior to forming a trim process (described below), the second nanostructures 66 in both the n-type region 50N and the p-type region 50P may have approximately the same size and shape.

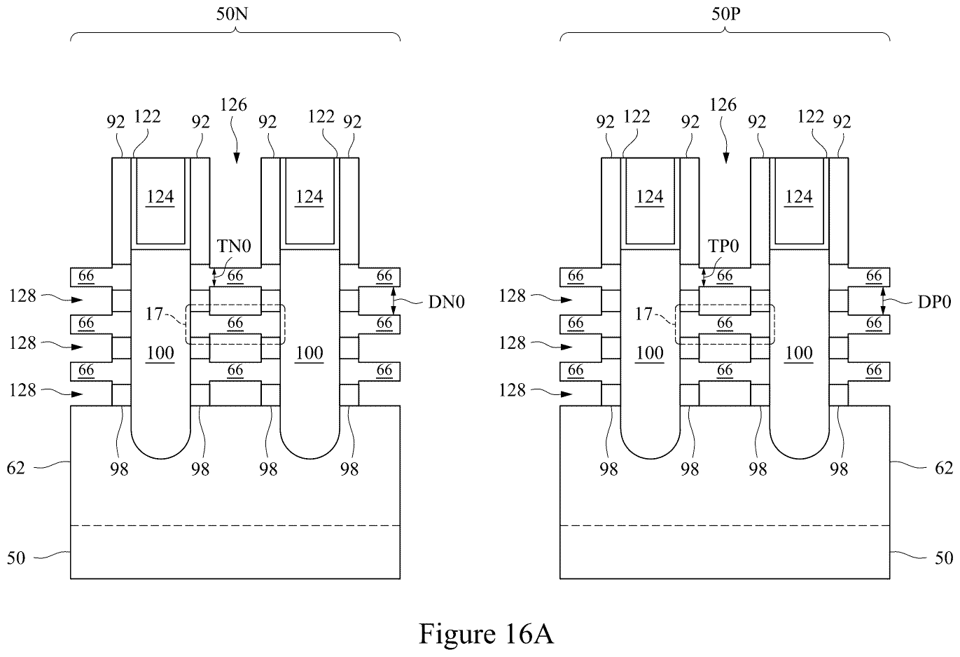

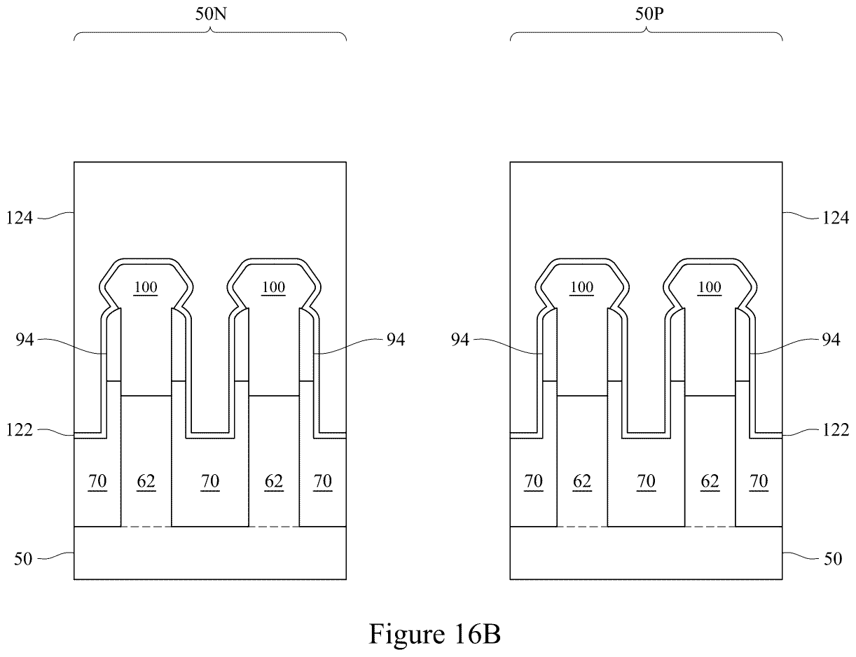

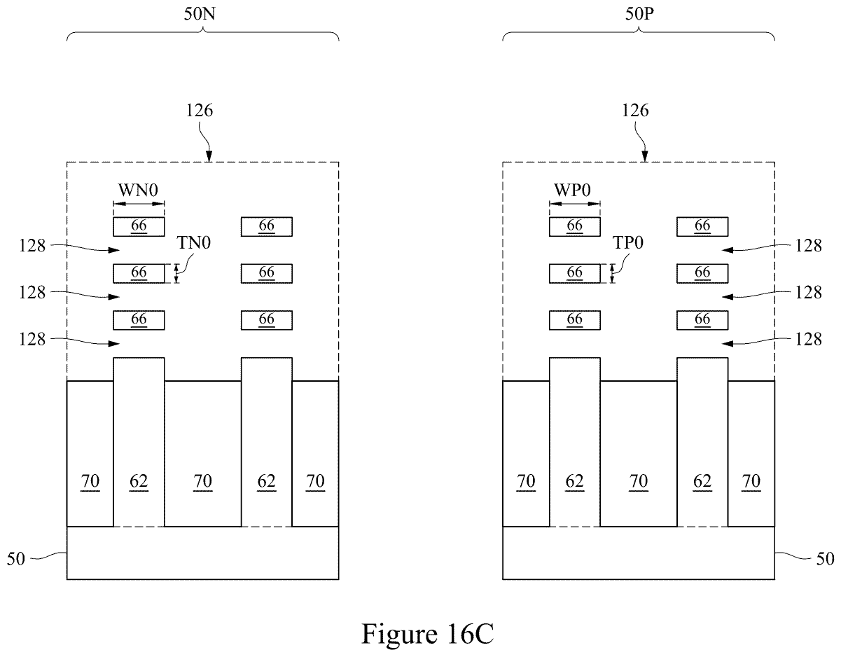

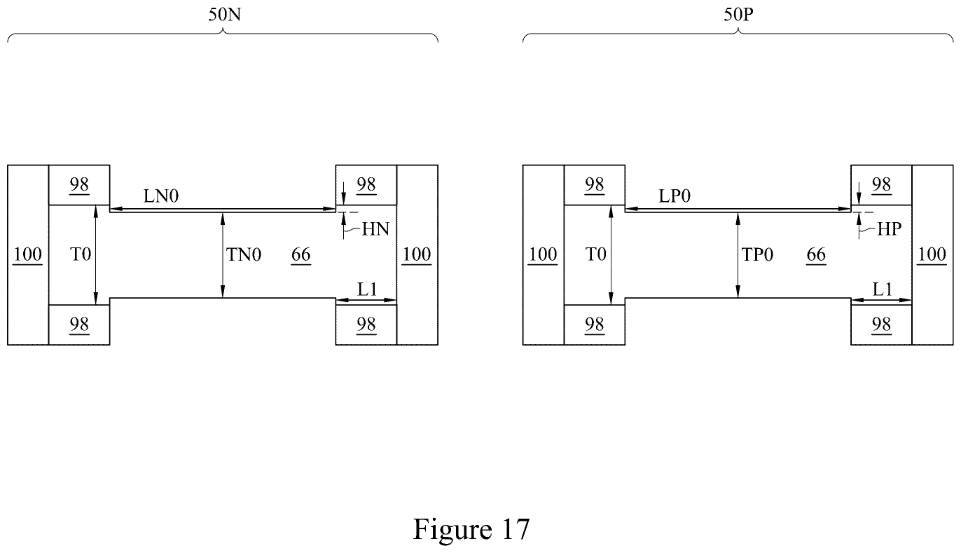

In FIGS. 16A-16C, a trim process is performed to decrease the thicknesses of the exposed portions of the nanostructures 66 and expand the openings 128, in accordance with some embodiments. After performing the trim process, the nanostructures 66 may be referred to as “trimmed nanostructures 66” herein. FIG. 17 illustrates magnified regions of the n-type region 50N and the p-type region 50P including trimmed nanostructures 66, which regions may be similar to the regions 17 indicated in FIG. 16A. The trim process may comprise, for example, a separate second etch process performed after the first etch process that removed the first nanostructures 64 (see FIGS. 15A-15C). In other embodiments, the trim process may be considered part of the first etch process that removed the first nanostructures 64. The trim process may recess exposed surfaces (e.g., top surfaces and bottom surfaces) of the nanostructures 66. The trim process may be a single process performed on the nanostructures 66 in the n-type region 50N and the p-type region 50P simultaneously. For example, the trim process may be performed without separately masking or protecting the n-type region 50N or the p-type region 50P. In some embodiments, the same trim process may trim (e.g., etch or recess) the nanostructures 66 of the n-type region 50N a different amount (e.g., depth) than the nanostructures 66 of the p-type region 50P. Trimming the nanostructures 66 in the n-type region 50N and the p-type region 50P different amounts using the same trimming process can allow for improved design flexibility and improved device performance.

In some embodiments, the trim process trims the nanostructures 66 in the n-type region 50N a different amount than the nanostructures 66 in the p-type region 50P. In some embodiments, the trim process may be any acceptable etch process that selectively etches the material of the nanostructures 66 in the n-type region 50N at a different rate than the material of the nanostructures 66 in the p-type region 50P. In some embodiments, the trim process comprises an isotropic etch process. In some embodiments, the trim process comprises a wet etch process using tetramethylammonium hydroxide (TMAH) or the like, though other selective etches are possible. Other etch processes are possible, such as standard clean 1 (SC1 ), NH₄OH/H₂O₂/H₂O, diluted NH₄OH, or the like.

In some embodiments, the etch rate of the nanostructures 66 may depend on the dopant and/or doping concentration of the nanostructures 66. Accordingly, in some embodiments, the etch rate of nanostructures 66 doped with n-type dopants (e.g., in the n-type region 50N) may be different than the etch rate of nanostructures 66 doped with p-type dopants (e.g., in the p-type region 50P). For example, in some embodiments, the nanostructures 66 in the p-type region 50P may be etched more than the nanostructures 66 in the n-type region 50N by the same trim process step. In other embodiments, the nanostructures 66 in the n-type region 50N may be etched more than the nanostructures 66 in the p-type region 50P by the same trim process step. In some embodiments, the selectivity of the trim process may depend on the absolute or relative doping concentrations of the nanostructures 66 in the n-type region 50N and of the nanostructures 66 in the p-type region 50P. For example, in some embodiments, the trim process may etch nanostructures 66 having a higher doping concentration at a greater rate than nanostructures 66 having a lower doping concentration. In some embodiments, the selectivity of the trim process may depend on the concentration of silicon germanium remaining in or on the nanostructures 66 after removing the first nanostructures 64.

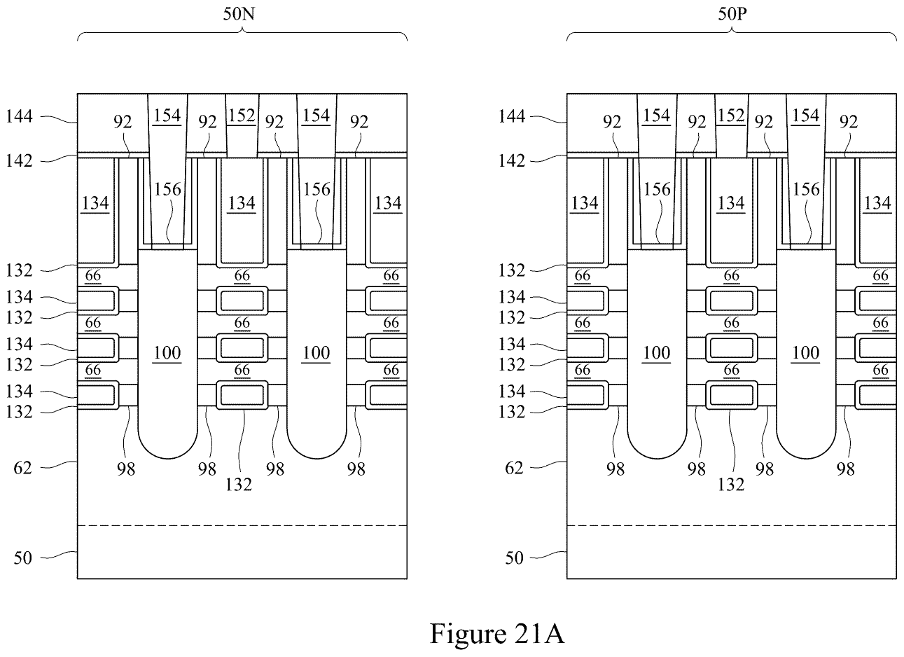

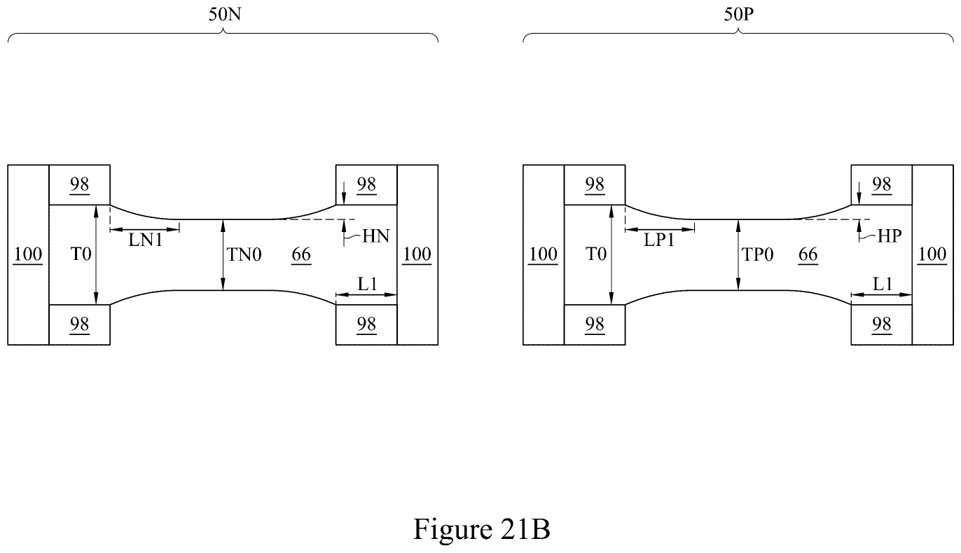

FIGS. 16A through 20C illustrate the trimmed (e.g., etched) portions of the trimmed nanostructures 66 as having flat (e.g., planar) surfaces, but the trim process may result in trimmed nanostructures 66 having other profiles, such as concave surfaces, stepped surfaces, or other surface profiles. Examples of trimmed nanostructures 66 having concave surfaces is described below for FIGS. 21A-21B. Additionally, for illustrative purposes, FIG. 16A-20C illustrate the trimmed nanostructures 66 in the p-type region 50P as having smaller dimensions (e.g., are “more trimmed”) than the trimmed nanostructures 66 in the n-type region 50N. In other embodiments, the trimmed nanostructures 66 in the n-type region 50N may have smaller dimensions than the trimmed nanostructures 66 in the p-type region 50P. The relative or absolute dimensions of the trimmed nanostructures 66 may be different than described or shown for FIGS. 16A-21B.

As shown in FIG. 17, the “untrimmed” portions of the nanostructures 66 may have a thickness T0, which may be approximately the same as the thickness T0 described previously for FIGS. 15A-15C. The trim process may etch the nanostructures 66 such that trimmed portions of the nanostructures 66 may be thinner than untrimmed portions of the same nanostructures 66. In some embodiments, after the trim process, the trimmed portions of the nanostructures 66 in the n-type region 50N may have a thickness TN0 that is smaller than T0, such as a thickness TN0 in the range of about 2 nm to about 8 nm, though other thicknesses are possible. A height difference HN between a surface of a trimmed portion and a surface of an untrimmed portion of the nanostructures 66 in the n-type region 50N may be in the range of about 0.5 nm to about 1.5 nm, though other heights are possible. In some embodiments, after the trim process, the trimmed portions of the nanostructures 66 in the p-type region 50P may have a thickness TP0 that is smaller than T0, such as a thickness TP0 in the range of about 2 nm to about 8 nm, though other thicknesses are possible. In some embodiments, TP0 is smaller than TN0. A height difference HP between a surface of a trimmed portion and a surface of an untrimmed portion of the nanostructures 66 in the p-type region 50P may be in the range of about 0.5 nm to about 1.5 nm, though other heights are possible. The height difference HN or HP may correspond to the depth that a top or bottom surface of a nanostructure 66 is recessed by the trim process.

In some embodiments, the trim process may etch the nanostructures 66 in the n-type region 50N differently than the nanostructures 66 in the p-type region 50P, as described previously. Accordingly, in some embodiments, the thickness TN0 and the thickness TP0 may be different. For example, in some embodiments, the thickness TN0 and the thickness TP0 may have a thickness difference in the range of about 0 nm to about 3 nm, though other differences are possible. For example, the difference TN0-TP0 may be in the range of about −3 nm to about +3 nm. Additionally, the height differences HN or HP may be different, in some embodiments.

In some embodiments, the trimmed nanostructures 66 in the n-type region 50N may have a sheet length LN0 in the range of about 5 nm to about 30 nm, and the trimmed nanostructures 66 in the p-type region 50P may have a sheet length LP0 in the range of about 5 nm to about 30 nm. In some embodiments, the sheet lengths LN0 and LP0 are approximately the same. In other embodiments, the sheet lengths LN0 and LP0 may be different. For example, in some embodiments, the sheet length LN0 and the sheet length LP0 may have a length difference in the range of about 0 nm to about 3 nm, though other differences are possible. In some embodiments, a length L1 of an untrimmed portion of a trimmed nanostructure 66 may be in the range of about 2 nm to about 8 nm, though other lengths are possible. The length L1 in the n-type region 50N may be different than the length L1 in the p-type region 50P, in some cases. In some embodiments, a vertical distance DN0 between neighboring trimmed nanostructures 66 in the n-type region 50N or a vertical distance DP0 between neighboring trimmed nanostructures 66 in the p-type region 50P may be in the range of about 3 nm to about 15 nm, though other distances are possible. In some embodiments, the trimmed nanostructures 66 in the n-type region 50N have a width WN0 in the range of about 5 nm to about 80 nm, and the trimmed nanostructures 66 in the p-type region 50P have a width WP0 in the range of about 5 nm to about 80 nm. The widths WN0 and WP0 may be similar or different. For example, in some embodiments, WP0 is smaller than WN0. Other dimensions are possible.

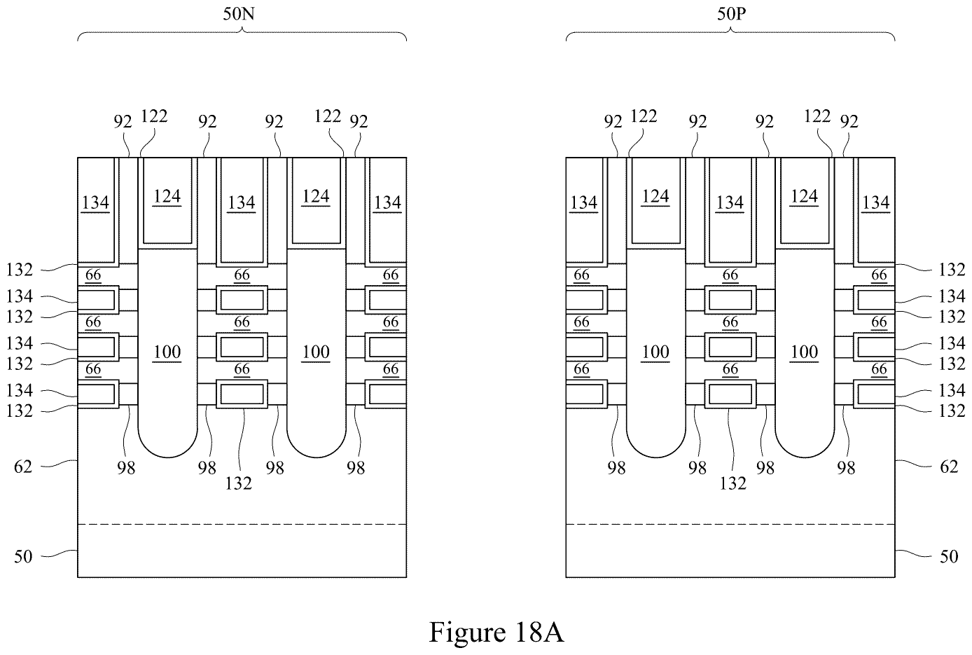

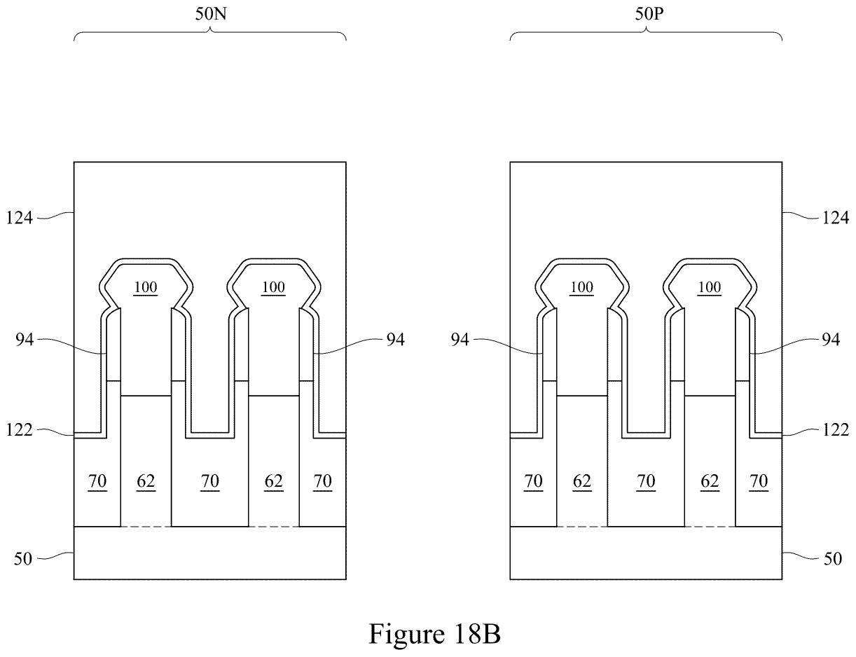

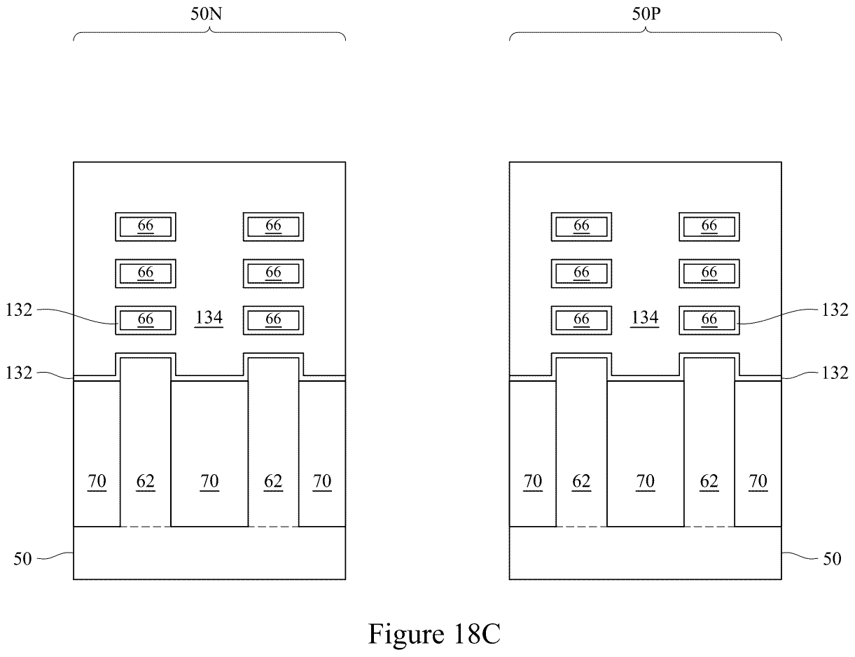

In FIGS. 18A-18C, gate dielectrics 132 and gate electrodes 134 are formed for replacement gates, in accordance with some embodiments. Each respective pair of a gate dielectric 132 and a gate electrode 134 may be collectively referred to as a “gate structure” or a “gate stack.” Each gate structure is wrapped around a channel region (e.g., a trimmed portion) of a nanostructure 66, such that the gate structure extends along sidewalls, a bottom surface, and a top surface of the nanostructure 66. Some of the gate structures also extend along sidewalls and/or a top surface of a fin 62.

The gate dielectrics 132 include one or more gate dielectric layer(s) disposed on the sidewalls and/or the top surfaces of the fins 62; on the top surfaces, the sidewalls, and the bottom surfaces of the channel regions (e.g., the trimmed portions) of the nanostructures 66; on the sidewalls of the inner spacers 98 adjacent the source/drain regions 103/113; and on the sidewalls of the gate spacers 92. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The gate electrodes 134 include one or more gate electrode layer(s) disposed over the gate dielectrics 132. The gate electrodes 134 may be formed of a metal-containing material such as titanium nitride, titanium oxide, tantalum nitride, tantalum carbide, tungsten, cobalt, ruthenium, aluminum, combinations thereof, multi-layers thereof, or the like. Although single-layered gate electrodes 134 are illustrated, the gate electrodes 134 may include any number of work function tuning layers, any number of barrier layers, any number of glue layers, and a fill material.

As an example to form the gate structures, one or more gate dielectric layer(s) may be deposited in the recesses 126 and the openings 128. The gate dielectric layer(s) may also be deposited on the top surfaces of the first ILD 124, the CESL 122, and the gate spacers 92. Subsequently, one or more gate electrode layer(s) may be deposited on the gate dielectric layer(s), and in the remaining portions of the recesses 126 and the openings 128. A removal process may then be performed to remove the excess portions of the gate dielectric layer(s) and the gate electrode layer(s), which excess portions are over the top surfaces of the first ILD 124, the CESL 122, and the gate spacers 92. In some embodiments, a planarization process such as a chemical mechanical polish (CMP), an etch-back process, combinations thereof, or the like may be utilized. The gate dielectric layer(s), after the removal process, have portions left in the recesses 126 and the openings 128 (thus forming the gate dielectrics 132). The gate electrode layer(s), after the removal process, have portions left in the recesses 126 and the openings 128 (thus forming the gate electrodes 134). In some embodiments, gate structures in the p-type region 50P may be thicker than gate structures in the n-type region 50N. In some embodiments, a thickness of gate electrodes 134 in the p-type region 50P may be greater than a thickness of gate electrodes 134 in the n-type region 50N. In some embodiments, a thickness of gate dielectrics 132 in the p-type region 50P may be greater than a thickness of gate dielectrics 132 in the n-type region 50N. When a planarization process it utilized, the top surfaces of the gate spacers 92, the CESL 122, the first ILD 124, the gate dielectrics 132, and the gate electrodes 134 are level or coplanar (within process variations).

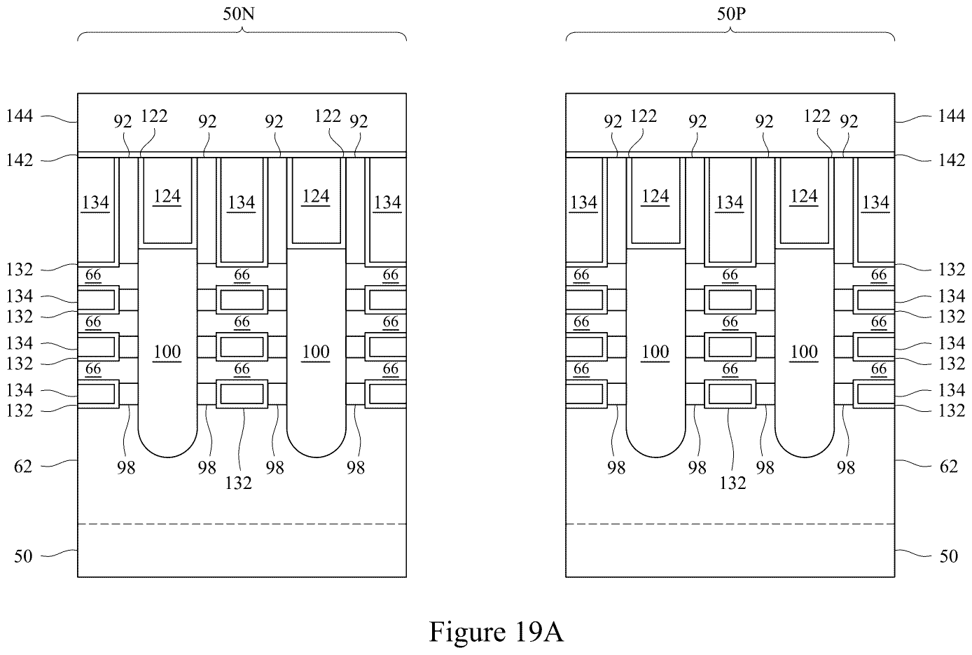

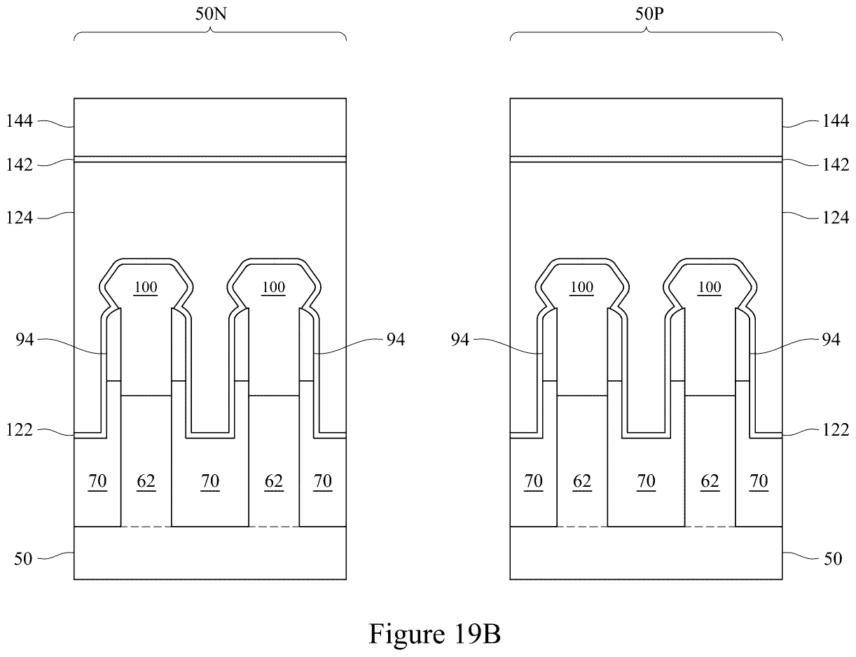

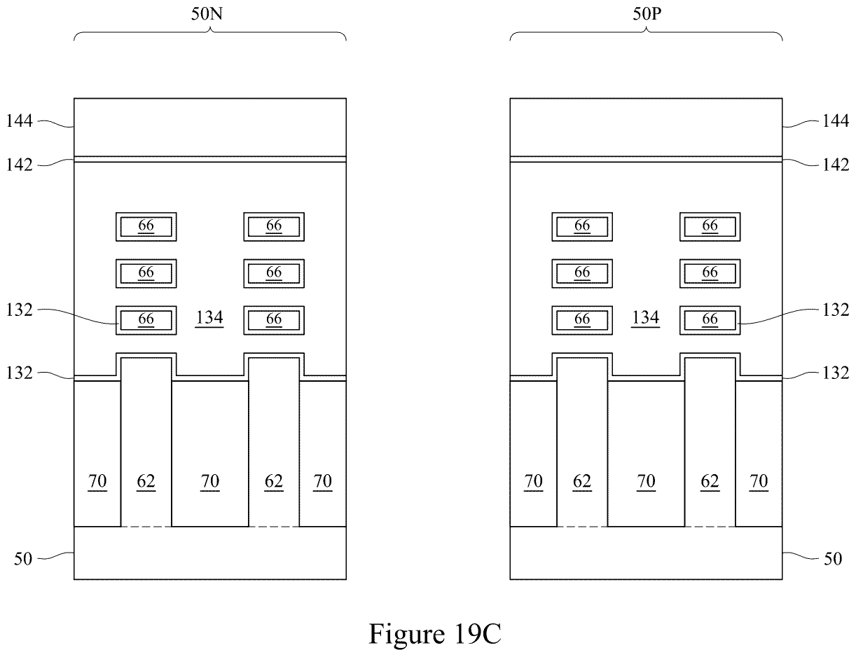

In FIGS. 19A-19C, a second ILD 144 is deposited over the gate spacers 92, the CESL 122, the first ILD 124, the gate dielectrics 132, and the gate electrodes 134. In some embodiments, the second ILD 144 is a flowable film formed by a flowable CVD method. In some embodiments, the second ILD 144 is formed of a dielectric material such as PSG, BSG, BPSG, USG, or the like, which may be formed by any suitable deposition process, such as CVD, PECVD, or the like. In an embodiment, the second ILD 144 is thinner than the first ILD 124

In some embodiments, an etch stop layer (ESL) 142 is formed between the second ILD 144 and the gate spacers 92, the CESL 122, the first ILD 124, the gate dielectrics 132, and the gate electrodes 134. The ESL 142 may be formed of a dielectric material having a high etching selectivity from the etching of the second ILD 144, such as silicon nitride, silicon oxide, silicon oxynitride, or the like, which may be formed by any suitable deposition process, such as CVD, ALD, or the like.

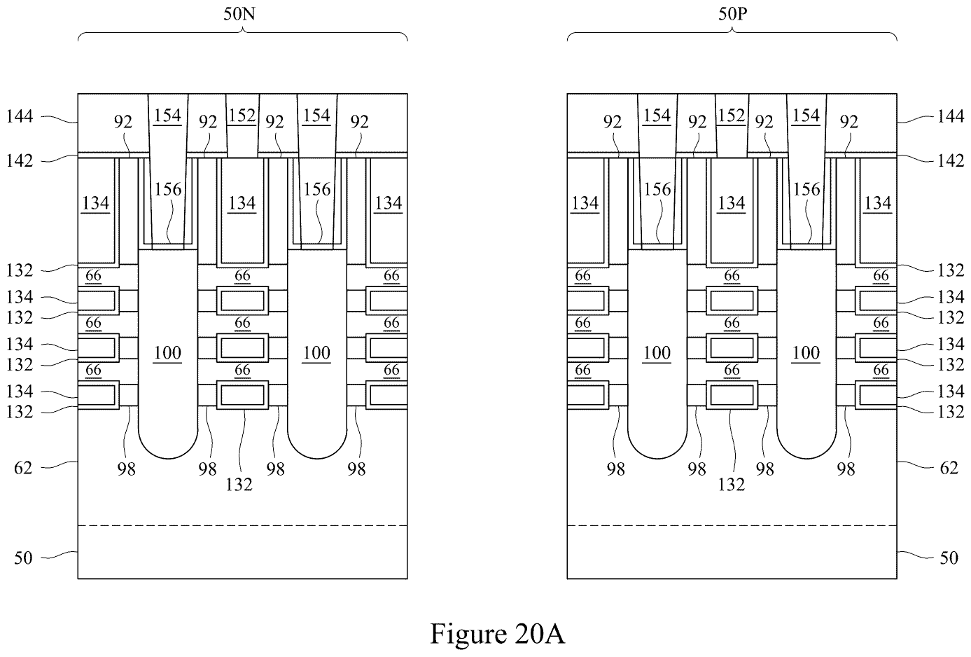

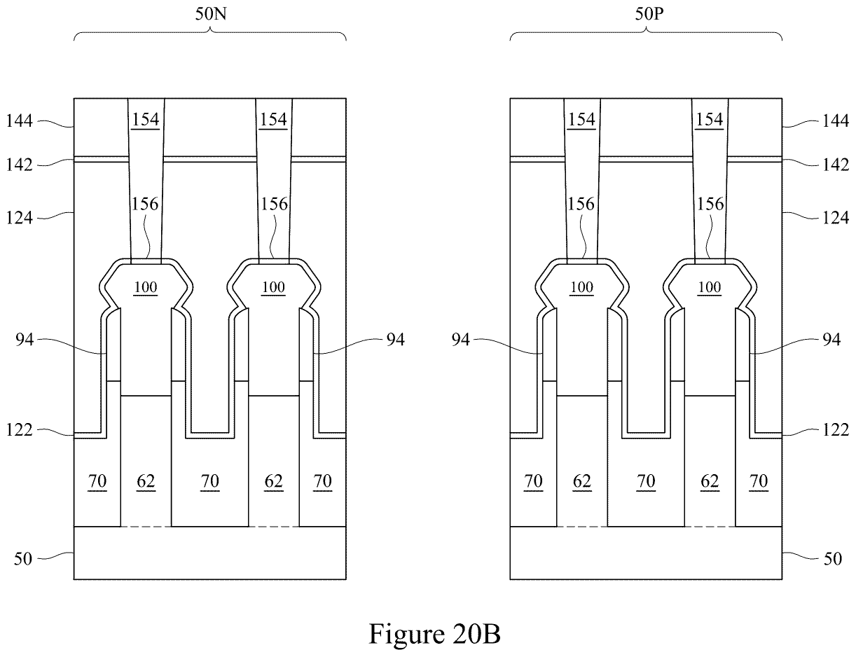

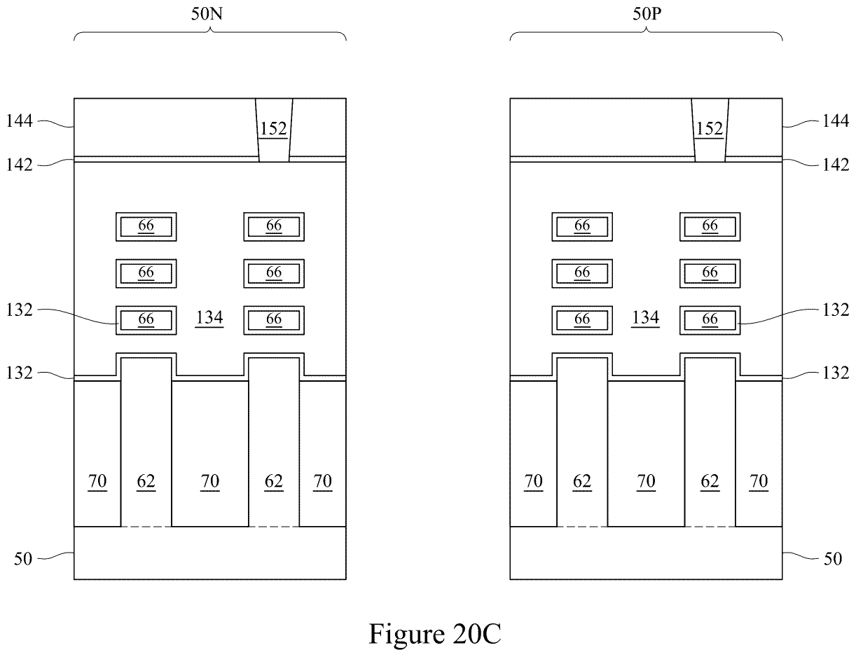

In FIGS. 20A-20C, gate contacts 152 and source/drain contacts 154 are formed to contact, respectively, the gate electrodes 134 and the source/drain regions 103/113. The gate contacts 152 may be physically and electrically coupled to the gate electrodes 134. The source/drain contacts 154 may be physically and electrically coupled to the source/drain regions 103/113.

As an example to form the gate contacts 152 and the source/drain contacts 154, openings for the gate contacts 152 are formed through the second ILD 144 and the ESL 142, and openings for the source/drain contacts 154 are formed through the second ILD 144, the ESL 142, the first ILD 124, and the CESL 122. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 144. The remaining liner and conductive material form the gate contacts 152 and the source/drain contacts 154 in the openings. The gate contacts 152 and the source/drain contacts 154 may be formed in distinct processes, or may be formed in the same process. Although shown as being formed in the same cross-sections, it should be appreciated that each of the gate contacts 152 and the source/drain contacts 154 may be formed in different cross-sections, which may avoid shorting of the contacts.

Optionally, metal-semiconductor alloy regions 156 are formed at the interfaces between the source/drain regions 103/113 and the source/drain contacts 154. The metal-semiconductor alloy regions 156 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 156 can be formed before the material(s) of the source/drain contacts 154 by depositing a metal in the openings for the source/drain contacts 154 and then performing a thermal annealing process. The metal can be any metal capable of reacting with the semiconductor materials (e.g., silicon, silicon carbide, silicon germanium, germanium, etc.) of the source/drain regions 103/113 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 154, such as from surfaces of the metal-semiconductor alloy regions 156. The material(s) of the source/drain contacts 154 can then be formed on the metal-semiconductor alloy regions 156.

FIG. 21A illustrates a structure similar to that shown in FIG. 20A, except that the trimmed nanostructures 66 have concave surfaces rather than flat surfaces. FIG. 21B illustrates magnified regions of a n-type region 50N and a p-type region 50P such as shown in FIG. 21A, including trimmed nanostructures 66, which regions may be similar to the regions 17 indicated in FIG. 16A. The trimmed nanostructures 66 shown in FIGS. 17 and 21A-21B are illustrative examples, and trimmed nanostructures 66 may have other shapes, profiles, or dimensions in other embodiments. In some embodiments, the gate stacks or layers thereof may have curved (e.g, convex) surfaces. In some embodiments, the same trim process trims the nanostructures 66 of the n-type region 50N a different amount than the nanostructures 66 of the p-type region 50P. For example, FIG. 21 illustrates the trimmed nanostructures 66 in the p-type region 50P as being trimmed a greater amount than the trimmed nanostructures 66 in the n-type region 50N. In other embodiments, the trimmed nanostructures 66 in the n-type region 50N may be trimmed a greater amount than the trimmed nanostructures 66 in the p-type region 50P. The relative or absolute dimensions of the trimmed nanostructures 66 may be different than described or shown for FIG. 21.

As shown in FIG. 21, the etching of the trim process etches the nanostructures 66 such that the top trimmed surface and bottom trimmed surface of each nanostructure 66 has a concave profile after performing the trim process. Accordingly, the trim process etches the nanostructures 66 such that trimmed portions of the nanostructures 66 may be thinner than untrimmed portions of the same nanostructures 66. In some cases, a central trimmed surface of a trimmed nanostructure 66 may be approximately flat. In other cases, the top and bottom trimmed surfaces of a trimmed nanostructures 66 are substantially curved.

In some cases, the “untrimmed” portions of the nanostructures 66 may have a thickness T0, which may be approximately the same as the thickness T0 described previously for FIGS. 15A-15C. In some embodiments, after the trim process, the trimmed portions of the nanostructures 66 in the n-type region 50N may have a thickness TN0 in the range of about 2 nm to about 8 nm, though other thicknesses are possible. A height difference HN between a surface of a trimmed portion and a surface of an untrimmed portion of the nanostructures 66 in the n-type region 50N may be in the range of about 0.5 nm to about 1.5 nm, though other heights are possible. In some embodiments, after the trim process, the trimmed portions of the nanostructures 66 in the p-type region 50P may have a thickness TP0 in the range of about 2 nm to about 8 nm, though other thicknesses are possible. A height difference HP between a surface of a trimmed portion and a surface of an untrimmed portion of the nanostructures 66 in the p-type region 50P may be in the range of about 0.5 nm to about 1.5 nm, though other heights are possible.

In some embodiments, the trim process may etch the nanostructures 66 in the n-type region 50N differently than the nanostructures 66 in the p-type region 50P, as described previously. Accordingly, in some embodiments, the thickness TN0 and the thickness TP0 may be different. For example, in some embodiments, the thickness TN0 and the thickness TP0 may have a thickness difference in the range of about 0 nm to about 3 nm, though other differences are possible. For example, the difference TN0-TP0 may be in the range of about −3 nm to about +3 nm. In some embodiments, the height difference HN and the height difference HP may have a difference in the range of about 0 nm to about 3 nm. For example, the difference HN-HP may be in the range of about −3 nm to about +3 nm.

In some embodiments, a length LN1 from an edge of the trimmed portion to a substantially flat central surface of the nanostructures 66 in the n-type region 50N may be in the range of about 0 nm to about 6 nm. In some embodiments, a length LP1 from an edge of the trimmed portion to a substantially flat central surface of the nanostructures 66 in the p-type region 50P may be the range of about 0 nm to about 6 nm. A difference between LN1 and LP1 may be in the range of about 0 nm to about 3 nm. For example, the difference LN1-LP1 may be in the range of about −3 nm to about +3 nm. The lengths LN1 or LP1 may correspond to the length of a curved surface of a nanostructure 66. In some embodiments, a length L1 of an untrimmed portion of a trimmed nanostructure 66 may be in the range of about 2 nm to about 8 nm, though other lengths are possible. The length L1 in the n-type region 50N may be different than the length L1 in the p-type region 50P, in some cases. In some embodiments, a vertical distance between neighboring trimmed nanostructures 66 may be in the range of about 3 nm to about 15 nm, though other distances are possible. Other dimensions are possible.

Embodiments may achieve advantages. For example, the methods and structures described herein provide a simple process for providing nanostructures having different thicknesses or different profiles in different regions of a device. More particularly, stacks of nanostructures having different thicknesses or profiles may be simultaneously formed using a single trim process with no extra patterning processes. The techniques described herein can allow for n-type nanostructures to be formed having different thicknesses or profiles than p-type nanostructures. The methods and structures provided herein can provide a tunable nanostructure height within separate regions of a wafer or device. The methods and structures provided herein may provide improved flexibility, improved device performance, reduced manufacturing cost, or a larger process window for wafer acceptance testing (WAT) control.

In an embodiment, a method includes forming a stack of n-type nanostructures over a substrate; forming a stack of p-type nanostructures over the substrate; performing a trim process on the stack of n-type nanostructures and the stack of p-type nanostructures, wherein the trim process etches surfaces of the n-type nanostructures at a first rate and etches surfaces of the p-type nanostructures at a second rate that is different from the first rate; forming a first gate structure on the stack of n-type nanostructures; and forming a second gate structure on the stack of p-type nanostructures. In an embodiment, the n-type nanostructures and the p-type nanostructures include silicon. In an embodiment, the stack of n-type nanostructures includes first dummy nanostructures and the stack of n-type nanostructures includes second dummy nanostructures, wherein the method further includes, before performing the trim process, performing an etch process to remove the first dummy nanostructures and the second dummy nanostructures. In an embodiment, the trim process includes a wet etch process using tetramethylammonium hydroxide (TMAH). In an embodiment, after performing the trim process, the p-type nanostructures have a first thickness and the n-type nanostructures have a second thickness that is greater than the first thickness. In an embodiment, before performing the trim process, the p-type nanostructures and the n-type nanostructures have the same third thickness. In an embodiment, the second thickness is between 0.1 nm and 3 nm greater than the first thickness. In an embodiment, after performing the trim process, the p-type nanostructures have a fourth thickness and the n-type nanostructures have a fifth thickness that is smaller than the fourth thickness.

In an embodiment, a method includes forming first nanostructures in a first region of a substrate; forming second nanostructures in a second region of the substrate; performing a first etch process to recess surfaces of the first nanostructures and the second nanostructures, wherein top surfaces and bottom surfaces of the first nanostructures are recessed a first depth by the first etch process, wherein top surfaces and bottom surfaces of the second nanostructures are recessed a second depth by the first etch process, wherein the first depth is greater than the second depth; and forming a first gate stack on the first nanostructures and a second gate stack on the second nanostructures. In an embodiment, a first doping concentration of the first nanostructures is greater than a second doping concentration of the second nanostructures. In an embodiment, after performing the first etch process, the top surfaces and bottom surfaces of the first nanostructures are concave. In an embodiment, the first doping concentration is a p-type doping concentration. In an embodiment, before performing the first etch process, performing a second etch process that removes silicon germanium from the first nanostructure and the second nanostructures. In an embodiment, the first depth is between 0 nm and 3 nm greater than the second depth. In an embodiment, after performing the first etch process, the top surfaces and bottom surfaces of the first nanostructures are flat. In an embodiment, after performing the first etch process, the first nanostructures have a first thickness that is smaller than a second thickness of the second nanostructures.

In an embodiment, a device includes first nanostructures over a substrate, wherein the first nanostructures are silicon, wherein first channel regions of the first nanostructures have a first thickness; second nanostructures over the substrate, wherein the second nanostructures are silicon, wherein second channel regions of the second nanostructures have a second thickness that is different from the first thickness; a first gate structure on the first nanostructures; and a second gate structure on the second nanostructures. In an embodiment, a difference between the first thickness and the second thickness is in the range of 0.1 nm to 3 nm. In an embodiment, the first channel regions are recessed a first depth, wherein the second channel regions are recessed a second depth, wherein the first depth is between 0 nm and 3 nm larger than the second depth. In an embodiment, the first channel regions have flat surfaces having a first length, wherein the second channel regions have flat surfaces having a second length, wherein the first length is different than the second length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of n-type nanostructures over a substrate;
forming a stack of p-type nanostructures over the substrate;
performing a trim process on the stack of n-type nanostructures and the stack of p-type nanostructures, wherein the trim process etches surfaces of the n-type nanostructures at a first rate and etches surfaces of the p-type nanostructures at a second rate that is different from the first rate;
forming a first gate structure on the stack of n-type nanostructures; and
forming a second gate structure on the stack of p-type nanostructures.

2. The method of claim 1, wherein the n-type nanostructures and the p-type nanostructures comprise silicon.

3. The method of claim 1, wherein the stack of n-type nanostructures comprises first dummy nanostructures and the stack of n-type nanostructures comprises second dummy nanostructures, wherein the method further comprises, before performing the trim process, performing an etch process to remove the first dummy nanostructures and the second dummy nanostructures.

4. The method of claim 1, wherein the trim process comprises a wet etch process using tetramethylammonium hydroxide (TMAH).

5. The method of claim 1, wherein, after performing the trim process, the p-type nanostructures have a first thickness and the n-type nanostructures have a second thickness that is greater than the first thickness.

6. The method of claim 5, wherein, before performing the trim process, the p-type nanostructures and the n-type nanostructures have the same third thickness.

7. The method of claim 5, wherein the second thickness is between 0.1 nm and 3 nm greater than the first thickness.

8. The method of claim 1, wherein, after performing the trim process, the p-type nanostructures have a fourth thickness and the n-type nanostructures have a fifth thickness that is smaller than the fourth thickness.

9. A method comprising:
forming first nanostructures in a first region of a substrate;
forming second nanostructures in a second region of the substrate;
performing a first etch process to recess surfaces of the first nanostructures and the second nanostructures, wherein top surfaces and bottom surfaces of the first nanostructures are recessed a first depth by the first etch process, wherein top surfaces and bottom surfaces of the second nanostructures are recessed a second depth by the first etch process, wherein the first depth is greater than the second depth; and
forming a first gate stack on the first nanostructures and a second gate stack on the second nanostructures.

10. The method of claim 9, wherein a first doping concentration of the first nanostructures is greater than a second doping concentration of the second nanostructures.

11. The method of claim 9, wherein, after performing the first etch process, the top surfaces and bottom surfaces of the first nanostructures are concave.

12. The method of claim 9, wherein the first doping concentration is a p-type doping concentration.

13. The method of claim 9 further comprising, before performing the first etch process, performing a second etch process that removes silicon germanium from the first nanostructure and the second nanostructures.

14. The method of claim 9, wherein the first depth is between 0 nm and 3 nm greater than the second depth.

15. The method of claim 9, wherein, after performing the first etch process, the top surfaces and bottom surfaces of the first nanostructures are flat.

16. The method of claim 9 wherein, after performing the first etch process, the first nanostructures have a first thickness that is smaller than a second thickness of the second nanostructures.

17. A device comprising:
a plurality of first nanostructures over a substrate, wherein the first nanostructures comprise silicon, wherein first channel regions of the first nanostructures have a first thickness;
a plurality of second nanostructures over the substrate, wherein the second nanostructures comprise silicon, wherein second channel regions of the second nanostructures have a second thickness that is different from the first thickness;
a first gate structure on the plurality of first nanostructures; and
a second gate structure on the plurality of second nanostructures.

18. The device of claim 17, wherein a difference between the first thickness and the second thickness is in the range of 0.1 nm to 3 nm.

19. The device of claim 17, wherein the first channel regions are recessed a first depth, wherein the second channel regions are recessed a second depth, wherein the first depth is between 0 nm and 3 nm larger than the second depth.

20. The device of claim 17, wherein the first channel regions comprise flat surfaces having a first length, wherein the second channel regions comprise flat surfaces having a second length, wherein the first length is different than the second length.
